(19) United States
(12) Patent Application Publication
(10) Pub. No.: US 2017/0373036 A1
(43) Pub. Date: Dec. 28, 2017

(54) DISPLAY DEVICE AND DRIVING METHOD OF DISPLAY DEVICE

(71) Applicant: Semiconductor Energy Laboratory Co., Ltd., Atsugi-shi (JP)

(72) Inventors: Shunpei YAMAZAKI, Tokyo (JP); Kei TAKAHASHI, Isehara (JP); Hideaki SHISHIDO, Atsugi (JP)

(21) Appl. No.: 15/622,244

(22) Filed: Jun. 14, 2017

(30) Foreign Application Priority Data
Jun. 24, 2016 (JP) 2016-125754
Jul. 1, 2016 (JP) 2016-131349

(51) Int. Cl. H01L 25/04; H01L 27/32; H01L 29/786; G09G 3/3233; H01L 27/12

(52) U.S. Cl. CPC H01L 25/048; H01L 27/3262; H01L 27/322; H01L 27/3211; G09G 2340/0407; H01L 27/1225; G09G 3/3233; H01L 29/7869; H01L 27/3213

(57) ABSTRACT

A display device includes first and second display elements, first to fourth transistors, and a first insulating layer. The first insulating layer is positioned between the second display element, the third transistor, the fourth transistor, the first display element, the first transistor, and the second transistor. The second display element has a function of emitting a second light on the first insulating layer side. The first display element has a function of emitting a first light to the same direction as the second light.

### TECHNICAL FIELD

One embodiment of the present invention relates to a display device.

Note that one embodiment of the present invention is not limited to the above technical field. Examples of the technical field of one embodiment of the present invention disclosed in this specification and the like include a semiconductor device, a display device, a light-emitting device, a lighting device, a power storage device, a memory device, a driving method thereof, and a manufacturing method thereof

### BACKGROUND ART

Display devices using organic electroluminescent (EL) elements or liquid crystal elements have been known. Examples of the display device also include a light-emitting device provided with a light-emitting element such as a light-emitting diode (LED), and electronic paper performing display with an electrophoretic method or the like.

The organic EL element generally has a structure in which a layer containing a light-emitting organic compound is provided between a pair of electrodes. By voltage application to this element, the light-emitting organic compound can emit light. A display device including such an organic EL element can be thin and lightweight and have high contrast and low power consumption.

Patent Document 1 discloses a flexible light-emitting device using an organic EL element.

### REFERENCE

### Patent Document

[Patent Document 1] Japanese Published Patent Application No. 2014-197522

### DISCLOSURE OF INVENTION

In recent years, high-definition display panels of portable information terminals, such as mobile phones, smartphones, and tablets, have also been developed. Accordingly, the display devices are required to have higher definition. For example, as compared to large-sized devices like home-use television sets, relatively small-sized portable information terminals such as cellular phones, smart phones, and tablet terminals need to have higher definition to have increased resolution.

An object of one embodiment of the present invention is to provide a display device with extremely high resolution. Another object is to provide a thin display device. Another object is to provide a highly reliable display device.

Note that the descriptions of these objects do not disturb the existence of other objects. In one embodiment of the present invention, there is no need to achieve all the objects. Objects other than the above objects can be derived from the description of the specification and like.

One embodiment of the present invention is a display device including a first display element, a second display element, a first transistor, a second transistor, a third transistor, a fourth transistor, and a first insulating layer. The first insulating layer is positioned above the second display element, the third transistor, and the fourth transistor. The first display element, the first transistor, and the second transistor are positioned above the first insulating layer. The first display element is electrically connected to the second transistor. The second display element is electrically connected to the fourth transistor. The first transistor is electrically connected to the second transistor. The third transistor is electrically connected to the fourth transistor. The second display element has a function of emitting a second light to a first insulating layer side. The first display element has a function of emitting a first light to the same direction as the second light.

In the above, each of the first display element and the second display element preferably includes a light-emitting layer. Each of the first display element and the second display element preferably includes a coloring layer overlapping with the light-emitting layer.

Another embodiment of the present invention is a display device including a first display element, a second display element, a third display element, a first transistor, a second transistor, a third transistor, a fourth transistor, and a first insulating layer. The first insulating layer is positioned above the second display element, the third transistor, and the fourth transistor. The first display element, the third display element, the first transistor, and the second transistor are positioned above the first insulating layer. The first display element is electrically connected to the second transistor. The second display element is electrically connected to the fourth transistor. The first transistor is electrically connected to the second transistor. The third transistor is electrically connected to the fourth transistor. The second display element has a function of emitting a second light to a first insulating layer side. The first display element has a function of emitting a first light to the same direction as the second light. The third display element has a function of emitting a first light to the same direction as the second light. The first display element and the third display element include different light-emitting layers.

Another embodiment of the present invention is a display device including a first display element, a second display element, a third display element, a first transistor, a second transistor, a third transistor, a fourth transistor, and a first insulating layer. The first insulating layer is positioned above the second display element, the third transistor, and the fourth transistor. The first display element, the third display element, the first transistor, and the second transistor are positioned above the first insulating layer. The first display element is electrically connected to the second transistor. The second display element is electrically connected to the fourth transistor. The first transistor is electrically connected to the second transistor. The third transistor is electrically connected to the fourth transistor. The first display element and the third display element include different light-emitting layers. The second display element is positioned between the first display element and the third display element when seen from the above.

Another embodiment of the present invention is a display device including a first display element, a second display element, a fourth display element, a first transistor, a second transistor, a third transistor, a fourth transistor, and a first insulating layer. The first insulating layer is positioned above the second display element, the fourth display element, the third transistor, and the fourth transistor. The first display element, the third display element, the first transistor, and the second transistor are positioned above the first insulating layer. The first display element is electrically connected to the second transistor. The second display element is electrically connected to the fourth transistor. The first transistor is electrically connected to the second transistor. The third transistor is electrically connected to the fourth transistor. The second display element has a function of emitting a second light to a first insulating layer side. The fourth display element has a function of emitting a fourth light to the first insulating layer side. The first display element has a function of emitting a first light to the same direction as the second light. The second display element and the fourth display element include different light-emitting layers.

Another embodiment of the present invention is a display device including a first display element, a second display element, a fourth display element, a first transistor, a second transistor, a third transistor, a fourth transistor, and a first insulating layer. The first insulating layer is positioned above the second display element, the fourth display element, the third transistor, and the fourth transistor. The first display element, the third display element, the first transistor, and the second transistor are positioned above the first insulating layer. The first display element is electrically connected to the second transistor. The second display element is electrically connected to the fourth transistor. The first transistor is electrically connected to the second transistor. The third transistor is electrically connected to the fourth transistor. The second display element and the fourth display element include different light-emitting layers. The first display element is positioned between the second display element and the fourth display element when seen from the above.

An adhesive layer is preferably included between the first insulating layer and the second display element.

In the above, the first transistor preferably includes a first source electrode and a first drain electrode. The second transistor is preferably positioned above the first transistor. One of the first source electrode and the first drain electrode preferably serves as a gate electrode of the second transistor.

The third transistor and the fourth transistor are preferably provided on the same plane.

The third transistor preferably includes a third source electrode and a third drain electrode. The second transistor is preferably positioned above the third transistor. One of the third source electrode and the third drain electrode preferably serves as a gate electrode of the fourth transistor.

In the above, the first light and the second light preferably are different in color.

In the above, the first display element and the second display element are preferably different in area.

In the above, the first display element and the second display element are preferably top emission light-emitting elements. Alternatively, the first display element and the second display element are preferably a top emission light-emitting element and a bottom emission light-emitting element, respectively.

In the above, at least one of the first transistor, the second transistor, the third transistor, and the fourth transistor preferably includes an oxide semiconductor in its semiconductor layer where a channel is formed.

Another embodiment of the present invention is a driving method of a display device including a first display element, a second display element, and a first insulating layer. The first insulating layer is positioned above the second display element. The first display element is positioned above the first insulating layer. The second display element has a function of emitting a second light to a first insulating layer side. The first display element has a function of emitting a first light to the same direction as the second light. The display device displays an image by switching between a first mode, a second mode, and a third mode. In the first mode, an image is displayed by driving the first display element and the second display element. In the second mode, an image is displayed by driving only the first display element. In the third mode, an image is displayed by driving only the second display element. The resolution of the image displayed in the second mode and the third mode are lower than that in the first mode.

In the above driving method, the resolution of the image displayed in the second mode and the third mode is preferably half that in the first mode.

According to one embodiment of the present invention, a display device with higher resolution, a thin display device, or a highly reliable display device can be provided.

Note that one embodiment of the present invention does not necessarily achieve all the effects listed above. Other effects can be derived from the description of the specification, the drawings, the claims, and the like.

### BRIEF DESCRIPTION OF DRAWINGS FIGS. 1A and 1B illustrate a display device according to one embodiment.

FIGS. 2A to 2C illustrate a display device according to one embodiment.

FIGS. 3A and 3B illustrate a display device according to one embodiment.

FIGS. 4A to 4C illustrate a display device according to one embodiment.

FIGS. 5A to 5C illustrate a display device according to one embodiment.

FIGS. 6A and 6B illustrate a display device according to one embodiment.

FIGS. 7A to 7C illustrate a display device according to one embodiment.

FIG. 8 illustrates a display device according to one embodiment.

FIGS. 9A and 9B illustrate a display device according to one embodiment.

FIGS. 10A and 10B illustrate a display device according to one embodiment.

FIG. 11 illustrates a display device according to one embodiment.

FIGS. 12A and 12B illustrate a display device according to one embodiment.

FIGS. 13A to 13C illustrate a display device according to one embodiment.

FIGS. 14A to 14D illustrate a display device according to one embodiment.

FIG. 15 illustrates a display device according to one embodiment.

FIGS. 16A and 16B illustrate a display device according to one embodiment.

FIGS. 17A and 17B illustrate a display device according to one embodiment.

FIGS. 18A and 18B illustrate a display device according to one embodiment.

FIG. 19 illustrates a display device according to one embodiment.

FIGS. 20A to 20E illustrate a display device according to one embodiment.

FIGS. 21A to 21C illustrate a display device according to one embodiment.

FIG. 22 illustrates a display device according to one embodiment.

FIG. 23 is a block diagram of a display device according to one embodiment.

FIG. 24 is a circuit diagram of a display device according to one embodiment.

FIG. 25 shows a structure example of a display module according to one embodiment.

FIGS. 26A to 26D illustrate electronic devices according to one embodiment.

FIGS. 27A to 27E illustrate electronic devices according to one embodiment.

FIGS. 28A to 28D illustrate electronic devices according to one embodiment.

### BEST MODE FOR CARRYING OUT THE INVENTION

Embodiments will be described in detail with reference to the drawings. Note that one embodiment of the present invention is not limited to the following description. It will be readily appreciated by those skilled in the art that modes and details of the present invention can be modified in various ways without departing from the spirit and scope of the present invention. Thus, the present invention should not be construed as being limited to the description in the following embodiments and example.

Note that in structures of the present invention described below, the same portions or portions having similar functions are denoted by the same reference numerals in different drawings, and a description thereof is not repeated. Furthermore, the same hatching pattern is applied to portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first,” “second,” and the like are used in order to avoid confusion among components and do not limit the number.

A transistor is a kind of semiconductor elements and can achieve amplification of current or voltage, switching operation for controlling conduction or non-conduction, or the like. A transistor in this specification includes an insulated-gate field effect transistor (IGFET) and a thin film transistor (TFT).

### Embodiment 1

In this embodiment, examples of a display device of one embodiment of the present invention will be described.

A display device of one embodiment of the present invention includes a first display element and a second display element. The first display element is positioned above an insulating layer (on the display-surface side or on the viewer's side). The second display element is positioned below the insulating layer. The first display element and the second display element have a region where they do not overlap with each other in a plan view. Light emitted from the first display element and light emitted from the second display element are extracted in the same direction. For example, the light emitted from the second display element passes through the insulating layer to be extracted to the viewer's side.

Such a structure achieves high resolution as compared to when the first display element and the second display element are provided on the same plane.

A light-emitting element including a light-emitting layer is suitably used as each of the first display element and the second display element. Note that a display element other than the light-emitting element can be used.

It is preferable that a transistor be electrically connected to each of the first display element and the second display element. The transistor is a transistor (hereinafter also referred to as driver transistor) for drive control of the first display element or the second display element. For example, when a light-emitting element is used as each of the first display element and the second display element, the transistor has a function of controlling the amount of current flowing through the light-emitting element. In addition to the transistor electrically connected to the first display element or the second display element, a transistor (hereinafter also referred to as selection transistor) having a function of controlling the selected/unselected state of a pixel (subpixel) is preferably provided.

It is preferable that the driver transistor and the selection transistor which are electrically connected to the first display element positioned on the viewer's side be stacked to partly overlap with each other. This can reduce the area occupied by a pixel circuit, and the resolution can be further increased. In addition, the area where light emitted from the second display element passes can be increased. Thus, the emission area of the second display element can be increased, and the aperture ratio can be increased. Particularly when light-emitting elements are used, the current density for obtaining required luminance can be decreased owing to the increased aperture ratio, and thus the reliability is increased.

Note that the driver transistor and the selection transistor which are electrically connected to the second display element positioned on the side opposite to the viewer's side may be stacked to partly overlap with each other or may be provided side by side on the same plane. When the two transistors are provided side by side on the same plane, they can be fabricated in the same process and thus the fabrication cost can be reduced.

For example, the display device can have a structure in which a first display panel including the first display element is stacked with a second display panel including the second display element with an adhesive layer therebetween. In the structure, it is preferable that each of the first display panel and the second display panel be connected to a driver circuit for driving pixels. The two display panels can thus be driven separately; therefore, the degree of freedom of selecting driving methods is increased, and the range of use is extended. For example, different images can be displayed on the first display panel and the second display panel. In addition, the chromaticity and luminance can be adjusted separately.

In the display device of one embodiment of the present invention, two display elements which are adjacent to each other when seen from the display-surface side can be provided on different planes. Owing to this, as compared to when the first display element and the second display element are provided side by side on the same plane, the distance between the display elements provided on the same plane can be increased without the constraint of resolution.

In one embodiment of the present invention, a white-light-emitting element including a common light-emitting layer between pixels showing different colors is preferably used as the light-emitting element so that light of different colors are emitted through coloring layers. The structure simplifies the fabrication process as compared to when light-emitting layers are formed separately for the pixels. In addition, there is no need to consider design rules which is defined by the minimum processing dimension, alignment accuracy, and the like for formation of the light-emitting layers. Thus, the distance between adjacent pixels can be further reduced and the resolution can be increased.

In another embodiment of the present invention, light-emitting layers of light-emitting elements are preferably formed separately for pixels showing different colors. Even when such a method of separately forming different light-emitting layers is used, a display device with extremely high resolution can be provided because, as described above, the distance between two adjacent light-emitting elements provided on the same plane can be increased. The use of the light-emitting elements in which light-emitting layers are formed separately for pixels showing different colors is preferable because the following effects can be obtained: the color purity can be increased, the light extraction efficiency can be improved, the driving voltage can be reduced, and the like.

A more specific example is described below with reference to drawings.

### STRUCTURE EXAMPLE 1 OF DISPLAY DEVICE

[Display Device 10a]

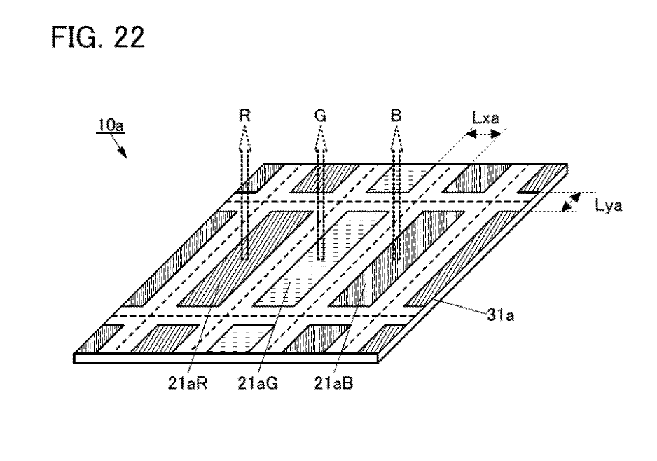

Shown first is a schematic perspective view of FIG. 22 in which a display device 10a includes a plurality of display devices above one plane.

The display device 10a includes display elements 21aR, 21aG, and 21aB over an insulating layer 31a. The display elements 21aR, 21aG, and 21aB emit red light R, green light G, and blue light B, respectively, toward a display-surface side.

A region surrounded by the dashed-dotted line in FIG. 22 is a region that may be occupied by one subpixel. The shape of the region is not limited to a rectangle as in FIG. 22. The region can have other shapes that can be periodically arranged.

The display elements 21aR, 21aG, and 21aB are arranged in a stripe pattern. Note that the display elements 21aR, 21aG, and 21aB have the same shape in this example.

As shown in FIG. 22, two display elements showing different colors are provided at an interval of a distance Lxa. Two display elements emitting the same color are provided at an interval of a distance Lya.

The distances Lxa and Lya depend on design rules which are defined by the minimum processing dimension, alignment accuracy between different layers, and the like for formation of the display elements and a pixel circuit. Thanks to the improvement of performance of apparatus, exposure technique, and the like, the minimum feature size and design rules for formation of the display elements and a pixel circuit can be reduced and tightened. Accordingly, the distances Lxa and Lya can be reduced.

However, it is difficult to simply reduce the distance Lxa between two display elements showing different colors for the following reasons.

When the distance Lxa is reduced simply, for example, mixture of colors between the display elements might occur. When the distance between two light-emitting elements which serve as display elements and emit different colors is reduced, undesired light emission might be generated due to leakage current between the light-emitting elements. This might lead to a reduction in display quality, such as mixture of colors and a reduction in contrast.

In addition, when a light-emitting element is used as the display element, for example, light-emitting layers can be formed separately for the light-emitting elements showing different colors. In the case where an island-shaped pattern is formed using a deposition method such as an evaporation method using a shadow mask or an ink-jet method, a part close to the outer edge may include a region that differs in thickness (a region with a small/large thickness). When the light-emitting layer is formed by such a method, the region that differs in thickness should not be positioned in a region contributing to light emission (a light-emitting region), each island-shaped pattern needs to be larger than the light-emitting region by the width of the region that differ in thickness. For this reason, there is a limit to the reduction in the distance Lxa between two adjacent light-emitting elements.

Note that the distance Lxa might differ between the display elements 21aR, 21aG, and 21aB which differ in shape. Also in that case, it is difficult to make the distance Lxa shorter than a predetermined value for the above-described reasons.

### [Display Device 10]

FIG. 1A is a schematic perspective view of a display device 10 of one embodiment of the present invention. FIG. 1B is a schematic view of the display device 10 when seen from the viewer's side (display-surface side).

The display device 10 has a stacked structure of insulating layers 31 and 32 each provided with a display element.

On the viewer's side, not the insulating layer 32 but the insulating layer 31 is positioned. The insulating layer 31 positioned on the viewer's side includes display elements 21R, 21G, and 21B. The insulating layer 32 includes display elements 22R, 22G, and 22B.

A direction along which display elements showing different colors are arranged is referred to as X direction. A direction along which display elements emitting the same color are arranged is referred to as Y direction. A thickness direction is referred to as Z direction.

In FIG. 1B, the outline of a display element formed on the insulating layer 31 is drawn by a solid line, whereas the outline of a display element formed on the insulating layer 32 is drawn by a dashed line. As shown in FIGS. 1A and 1B, the display element formed on the insulating layer 31 and the display element formed on the insulating layer 32 are alternately arranged in the X direction.

Light emitted from the display elements 22R, 22G, and 22B passes through the insulating layer 31 and is emitted to the viewer's side. In the example of FIG. 1A, light R and light B respectively emitted from the display element 21R and the display element 21B are ejected on the viewer's side, and light G emitted from the display element 22G passes through the insulating layer 31 and is ejected on the viewer's side.

In this structure, a region for allowing light from display elements which are positioned on the side opposite to the viewer's side to pass is provided between adjacent two of the display elements 21R, 21G, and 21B which are positioned on the viewer's side. In addition, a region overlapping with the display elements which are positioned on the viewer's side is provided between adjacent two of the display elements 22R, 22G, and 22B which are positioned on the side opposite to the viewer's side. Owing to this structure, two adjacent display elements over one insulating layer can be distanced without a decrease in resolution or aperture ratio.

In FIGS. 1A and 1B, a distance Lx, a distance Ly, and a distance Lp are shown. The distance Lx is a distance between two display elements showing different colors when seen from the display-surface side. The distance Ly is a distance between display elements emitting the same color. The distance Lp is a distance between two display elements showing different colors over one insulating layer.

In the display device 10, the distance Lx can be reduced without constraints of minimum processing dimension and design rules because two display elements which are adjacent to each other when seen from the viewer's side are provided over different insulating layers. In addition, the distance Lp between two adjacent display elements over one insulating layer is larger enough than the minimum distance defined by minimum feature size and design rules; thus, problems such as mixture of colors do not occur therebetween. Since problems such as mixture of colors are unlikely to occur between two display elements showing the same color over one insulating layer, the distance therebetween can be minimized within the constraints such as minimum processing dimension and design rules.

The distance Lp between two adjacent display elements over one insulating layer can also be large enough. Owing to this, variation in thickness in the emission area can be suppressed even when light-emitting layers of the display elements are separately formed as described above. As a result, a display device with high resolution and high display quality can be provided.

For these reasons, the widths in the X direction of the display elements 21R, 21G, and 21B which are positioned on the viewer's side and the display elements 22R, 22G, and 22B which are positioned on the side opposite to the viewer's side can be larger without sacrifice of resolution in the display device 10, as compared to that in the display device 10a shown in FIG. 22. The aperture ratio of the display device can thus be increased. The resolution can be further increased with no reduction in aperture ratio.

### [Transistor Arrangement]

In a display device, each pixel (subpixel) preferably includes a selection transistor for controlling the state of a pixel (subpixel) between selected and unselected. Particularly when a light-emitting element is used as a display element, a driver transistor for controlling the amount of current flowing through the light-emitting element is preferably included in addition to the selection transistor.

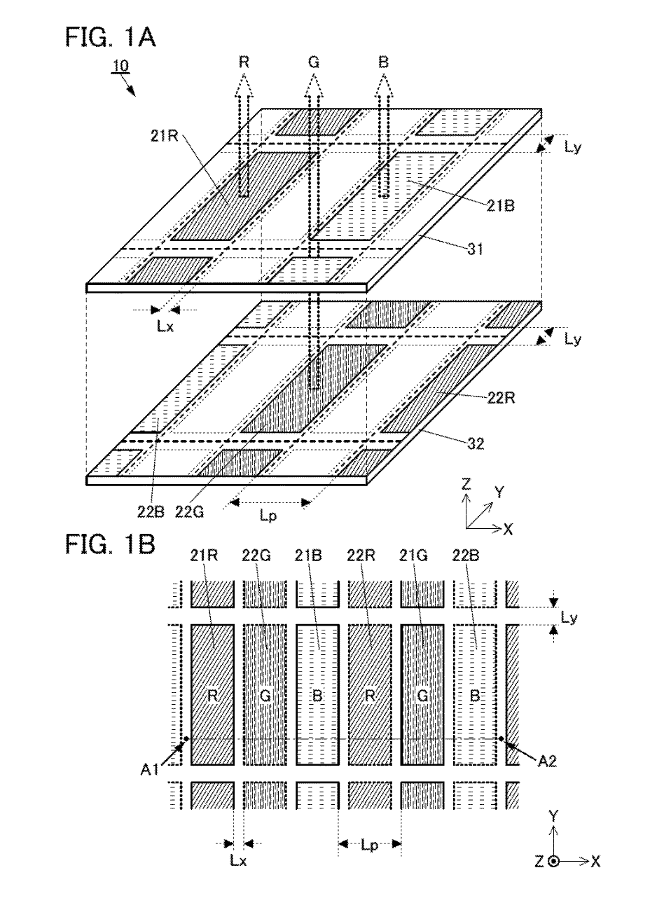

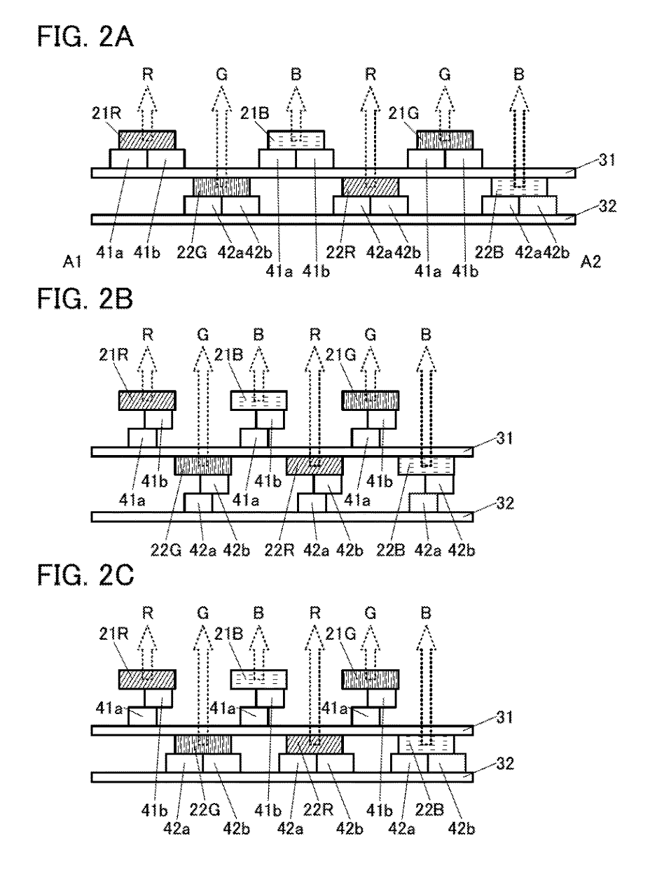

FIG. 2A is a schematic cross-sectional view of the display device 10 taken along section line A1-A2 in FIG. 1B.

A plurality of transistors 41a serving as selection transistors and a plurality of transistors 41b serving as driver transistors are provided over the insulating layer 31. The transistor 41b is electrically connected to the display element 21R, 21G, or 21B. The transistor 41a is electrically connected to the transistor 41b.

A plurality of transistors 42a serving as selection transistors and a plurality of transistors 42b serving as driver transistors are provided over the insulating layer 32. The transistor 42b is electrically connected to the display element 22R, 22G, or 22B. The transistor 42a is electrically connected to the transistor 42b.

In FIG. 2A, the transistors 41a and 41b are formed side by side on the same plane (the top surface of the insulating layer 31). Similarly, the transistors 42a and 42b are formed side by side on the same plane (the top surface of the insulating layer 32). In such a structure, the transistors 41a and 41b (the transistors 42a and 42b) can be formed concurrently in the same process, and the fabrication cost can thus be reduced.

FIG. 2B shows an example in which the transistors 41b and 42b are positioned above the transistors 41a and 42a, respectively. The total area occupied by these transistors which are stacked to each other can be smaller than the total area occupied by these transistors which are arranged side by side on the same plane.

The transistors 41a and 41b are preferably stacked to have a region overlapping each other. Similarly, the transistors 42a and 42b are preferably stacked to have a region overlapping each other.

FIG. 2C shows an example in which the transistors 41a and 41b are stacked and the transistors 42a and 42b are arranged side by side on the same plane. As shown in FIG. 2C, the total area occupied by the transistors 42a and 42b which are positioned below the insulating layer 31 is relatively large, but does not have effect on the aperture ratio and resolution of the display device. Thus, as compared to the structure shown in FIG. 2B, the fabrication cost can be further reduced while maintaining the same degree of aperture ratio and resolution.

The above is the description of the transistor arrangement.

### [Pixel Arrangement]

Another example of pixel arrangement which is different from the example shown in FIG. 1B and the like is described below.

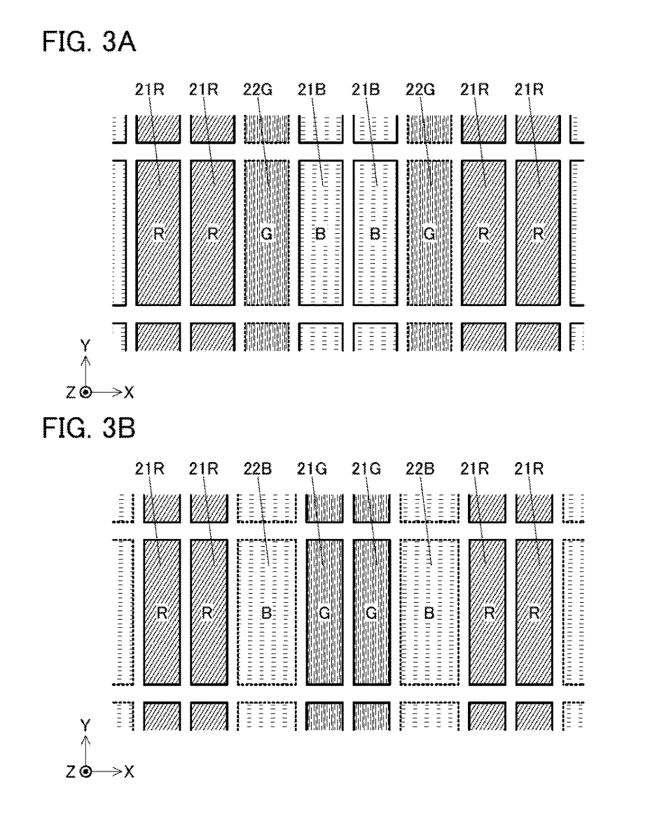

FIG. 3A is an example only including the display elements 21R, 22G, and 21B. Specifically, display elements for two color are provided above the insulating layer 31 (not shown), and display elements for another color are provided below the insulating layer 31 (not shown).

In addition, the display elements are arranged in FIG. 3A as follows: when seen from the viewer's side, two display elements 21R are adjacent to each other, two display elements 21B are adjacent to each other, and the display element 22G is sandwiched between the display elements 21R and 21B. In other words, two display elements showing different colors and positioned on the same plane are not adjacent to each other. This can prevent adverse effects such as mixture of colors.

In addition, display elements of two kinds are formed over the insulating layer 31 (not shown), and display elements of one kind are formed below the insulating layer 31 (not shown). Thus, the fabrication process can be simpler and easier than that of the example shown in FIG. 1B.

As described above, the display elements showing different colors and included in the display device may differ in shape. FIG. 3B is an example in which the display elements 21R and 21G are provided above the insulating layer 31 (not shown) and the display element 22B is provided below the insulating layer 31. In FIG. 3B, the width in the X direction of the display element 22B is larger than that of the display elements 21R and 21G. For example, when light-emitting elements are used as the display elements, a light-emitting element which emits blue light may be more likely to suffer from deterioration by light emission than other light-emitting elements. To take a measure against it, the area of the display element 22B emitting blue light is increased as shown in FIG. 3B. This can reduce the current density required for obtaining a predetermined level of luminance and improve the reliability.

In the examples shown in FIGS. 3A and 3B, two display elements emitting the same color are adjacent to each other and positioned over the insulating layer 31. For example, when light-emitting elements are used as the display elements, light-emitting layers showing different colors are separately formed (colored) using a shadow mask or the like. In that case, a continuous island-shaped light-emitting layer can be formed for these two display elements. Since the display elements below the insulating layer 31 emit the same color, there is no need to form their light-emitting layers separately. Thus, a higher-resolution display device can be fabricated even when the method using a shadow mask or the like is employed for forming a light-emitting layer.

Although the display elements in the example shown in FIG. 3A and the like are arranged in a stripe pattern, one embodiment of the present invention is not limited thereto. For example, each pixel may include four display elements, two in the X direction and two in the Y direction.

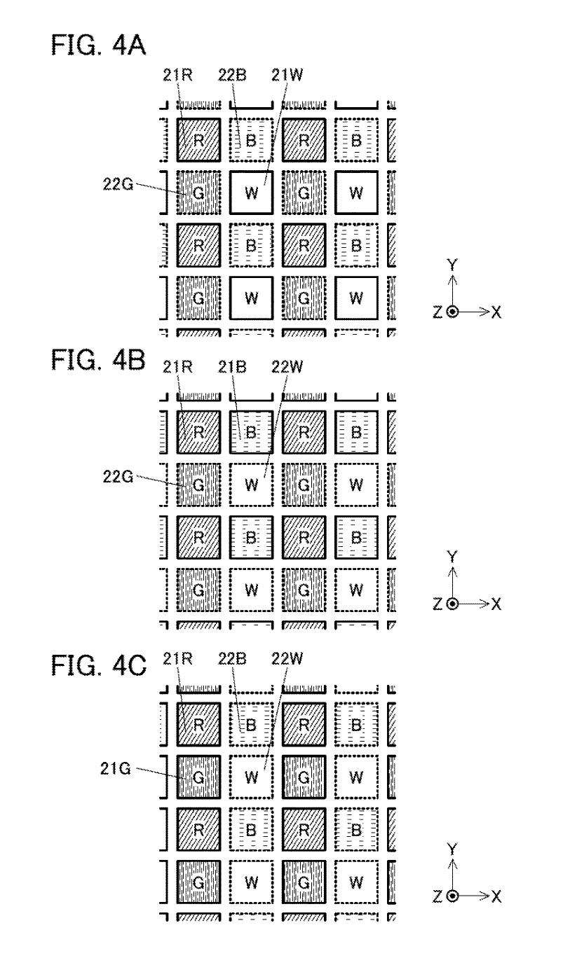

In an example of FIG. 4A, the display elements 21R and 22G are alternately arranged in the Y direction, and the display elements 22B and 21W are alternately arranged. In the example, the display elements 21R and 21W are arranged in a diagonal direction and positioned on the display surface side. The display elements 22B and 22G are positioned below the insulating layer 31 (not shown) which is on the display surface side.

Note that the display element 21W (and a display element 22W) is, for example, a display element emitting white light.

It is preferable that a display element positioned above the insulating layer 31 and a display element positioned below the insulating layer 31 be alternately arranged as shown in the example. The structure can achieve higher resolution because the distance between two display elements positioned on the same plane can be increased both in the X and Y directions.

Note that the following structure shown in FIG. 4B may be used: display elements arranged in the X direction are on the same plane; and in the Y direction, a display element positioned above the insulating layer 31 and a display element positioned below the insulating layer 31 are alternately arranged. The structure can have a small distance between adjacent display elements in the Y direction when seen from the viewer's side.

Note that the following structure shown in FIG. 4C may be used: display elements arranged in the Y direction are on the same plane; and in the X direction, a display element positioned above the insulating layer 31 and a display element positioned below the insulating layer 31 are alternately arranged. The structure can have a small distance between adjacent display elements in the X direction when seen from the viewer's side.

Note that the arrangement order of display elements is not limited to FIGS. 3A and 3B and FIGS. 4A to 4C, and the display elements can be replaced with each other. In addition, the shape and area of them is not limited thereto.

The above is the description of the pixel arrangement.

### [Display Mode]

Described below are examples of display modes that can be established by the display device of one embodiment of the present invention.

The display device 10 shown in FIGS. 1A and 1B and the like includes three kinds of display elements each above and below the insulating layer 31 (“above the insulating layer 31” means “on the viewer's side”). Thus, full color display can be obtained by driving the display elements of either side.

### [First Mode]

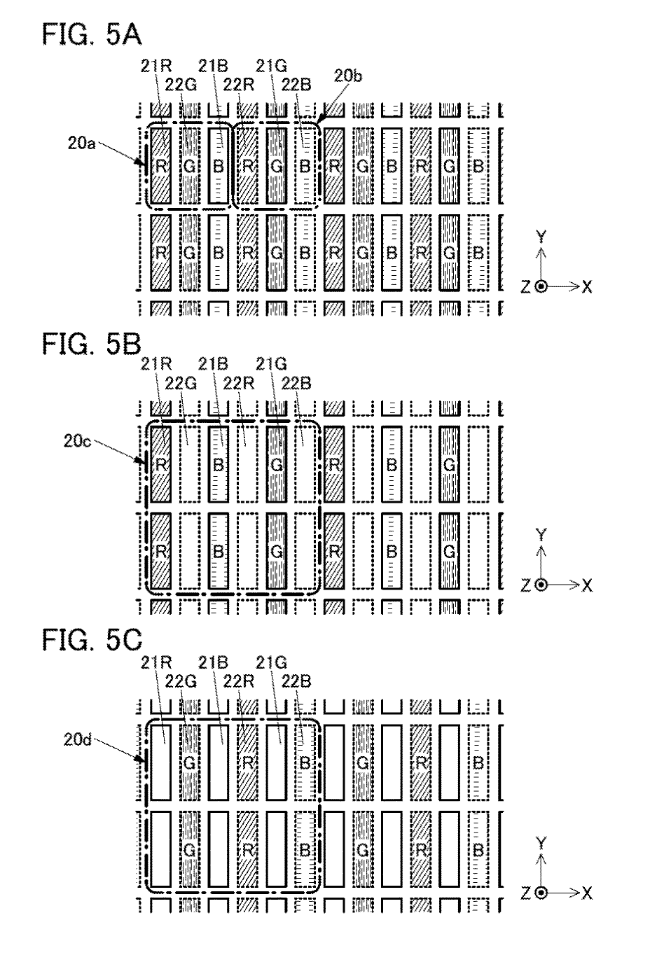

FIG. 5A is a schematic view showing a larger area by zooming out on FIG. 1B. In a pixel structure of FIG. 5A, two kinds of pixels, a pixel 20a and a pixel 20b, are alternately arranged in the X direction. The pixel 20a includes the display elements 21R, 22G, and 21B. The pixel 20b includes the display elements 22R, 21G, and 22B. In the first mode, bright images can be displayed with high resolution.

### [Second Mode]

FIG. 5B shows the second mode for displaying images by driving only the display elements 21R, 21G, and 21B which are positioned over the insulating layer 31 (not shown). In FIG. 5B, the display elements 22R, 22G, and 22B which are not driven are not filled with a hatching pattern.

In the second mode, a pixel 20c is twice as large as the pixel shown in FIG. 5A in the X and Y directions. That is, the definition in the display mode shown in FIG. 5B is half that in the mode shown in FIG. 5A. In the second mode, images can be displayed with low power consumption because the display elements 22R, 22G, and 22B positioned below the insulating layer 31 are not driven.

### [Third Mode]

FIG. 5C shows a third mode for displaying images by driving only the display elements 22R, 22G, and 22B which are positioned below the insulating layer 31 (not shown).

In the third mode, a pixel 20d is twice as large as the pixel shown in FIG. 5A in the X and Y directions, similarly in FIG. 5B, and the definition is half that in the mode shown in FIG. 5A. In the third mode, images can be displayed with low power consumption because the display elements 21R, 21G, and 21B positioned over the insulating layer 31 are not driven.

The first mode is preferable, for example, when high-luminance display is needed (e.g., outdoors in the daytime). The first mode is suitable for displaying still images or moving images at higher resolution because high-definition images can be displayed thereby.

In contrast, the second mode and the third mode are preferable when high-luminance display is not needed (e.g., indoors or outdoors in the nighttime). These modes are suitable for images which are not required to be displayed at high luminance, such as document data.

For example, an electronic device including the display device 10 can switch the first mode, the second mode, and the third mode depending on the definition of displayed image data. The electronic device may be configured to select the first mode when displaying a high-definition image and to select the second mode or the third mode when displaying a low-definition image.

For another example, the electronic device may include a sensor for obtaining brightness of the outside light and be configured to select the first mode in the bright environment and to select the second mode or the third mode in the dark environment.

The above is the description of the display mode.

### STRUCTURE EXAMPLE 2 OF DISPLAY DEVICE

A more specific structure example of the display device of one embodiment of the present invention is described below with reference to drawings.

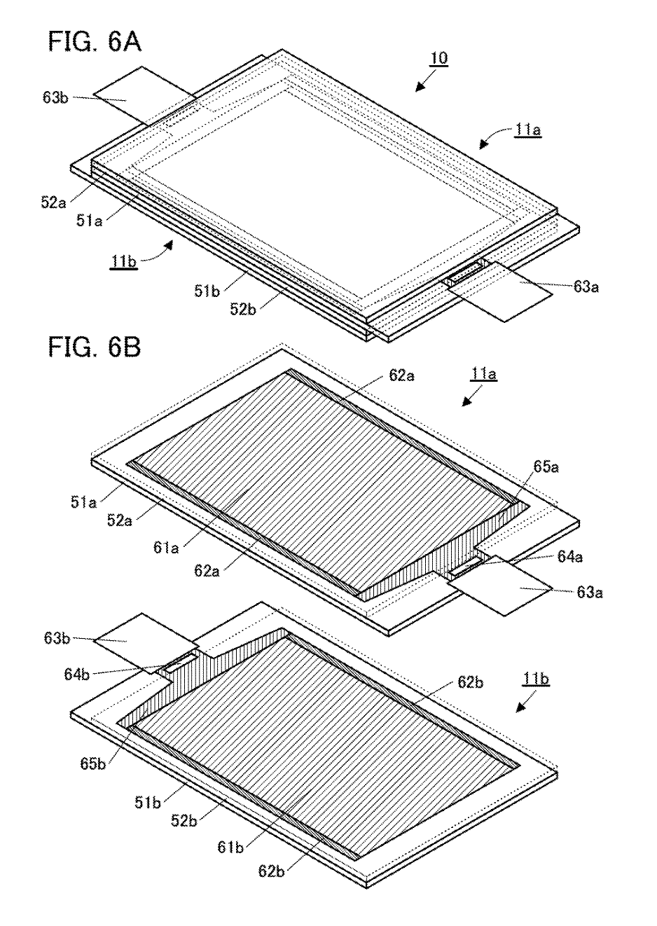

FIG. 6A is a perspective view of the display device 10. The display device 10 has a structure in which a display panel 11a is stacked with a display panel 11b. The display panel 11a is positioned on the viewer's side. The display panel 11b is positioned on the side opposite to the viewer's side.

FIG. 6B is a perspective view showing the display panel 11a and the display panel 11b separated from each other.

The display panel 11a includes a substrate 51a and a substrate 52a. The display panel 11b includes a substrate 51b and a substrate 52b. In FIG. 6B, the substrates 52a and 52b are illustrated by dashed lines along their outlines.

The display panel 11a includes a display portion 61a, a circuit portion 62a, a wiring 65a, and the like between the substrates 51a and 52a. In FIG. 6B, an IC 64a and an FPC 63a are mounted on the substrate 51a. Therefore, the display panel 11a illustrated in FIG. 6B can be referred to as a display module.

The display panel 11b includes a display portion 61b, a circuit portion 62b, a wiring 65b, and the like between the substrates 51b and 52b. In FIG. 6B, an IC 64b and an FPC 63b are mounted on the substrate 51b. Therefore, the display panel 11b illustrated in FIG. 6B can be referred to as a display module.

As the circuit portion 62a and the circuit portion 62b, a circuit functioning as a scan line driver circuit can be used, for example.

The wiring 65a has a function of supplying a signal and electric power to the display portion 61a and the circuit portion 62a. Similarly, the wiring 65b has a function of supplying a signal and electric power to the display portion 61b and the circuit portion 62b. The signal and electric power are input from outside through the FPC 63a or 63b or from the IC 64a or 64b.

In the example of FIG. 6B, the IC 64a and the IC 64b are respectively mounted on the substrate 51a and the substrate 51b by a chip on glass (COG) method or the like. As the IC 64a and the IC 64b, an IC serving as a scan line driver circuit or a signal line driver circuit can be used, for example. Note that the IC 64a and the IC 64b are not necessarily provided if not needed. The IC 64a and the IC 64b may be respectively mounted on the FPC 63a and the FPC 63b by a chip on film (COP) method or the like.

### CROSS-SECTIONAL STRUCTURE EXAMPLE 1 OF DISPLAY DEVICE

A cross-sectional structure example of the display device of one embodiment of the present invention is described below specifically. In the structure example, a display element includes a light-emitting element and a coloring layer.

### CROSS-SECTIONAL STRUCTURE EXAMPLE 1-1

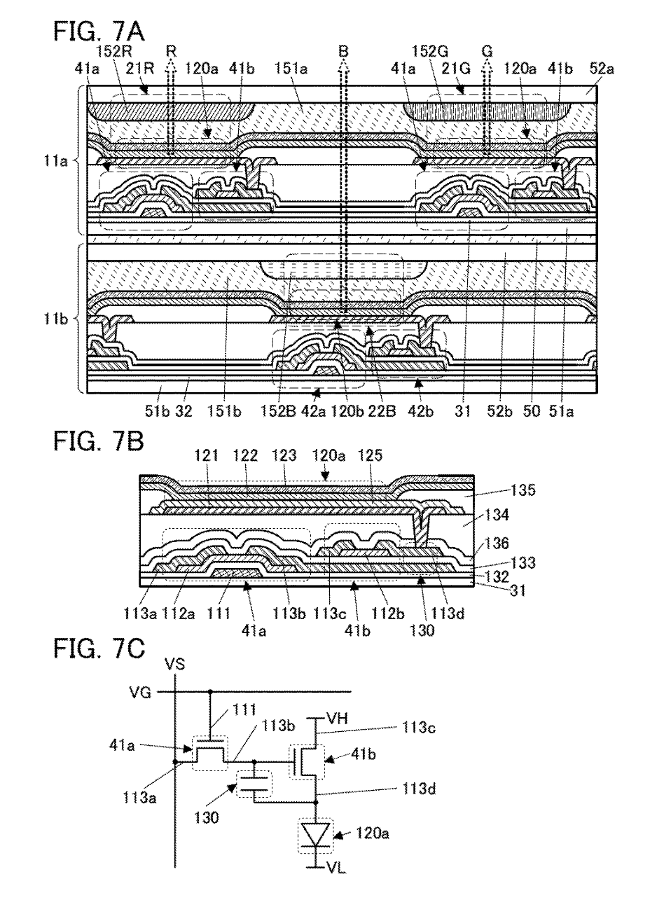

FIG. 7A is a schematic cross-sectional view of a display portion of the display device 10.

The display device 10 includes a display panel 11a and a display panel 11b which are bonded to each other with an adhesive layer 50.

The display panel 11a includes the transistor 41a, the transistor 41b, a light-emitting element 120a, a coloring layer 152R, a coloring layer 152G, a coloring layer 152B (not shown), an adhesive layer 151a, and the like, between the substrate 51a and the substrate 52a. The substrate 51a and the substrate 52a are bonded to each other with the adhesive layer 151a. The transistors 41a and 41b and the light-emitting element 120a are provided over the insulating layer 31.

The display panel 11b includes, between the substrate 51b and the substrate 52b, the transistor 42a, the transistor 42b, a light-emitting element 120b, the coloring layer 152R (not shown), the coloring layer 152G (not shown), the coloring layer 152B, an adhesive layer 151b, and the like. The substrate 51b and the substrate 52b are bonded to each other with the adhesive layer 151b. The transistor 42a, the transistor 42b, and the light-emitting element 120b are provided over the insulating layer 32. The substrate 52b and the substrate 51a are bonded to each other with the adhesive layer 50, and the display panel 11a and the display panel 11b are thus fixed to each other.

The display element 21R, the display element 21G, and the display element 21B (not shown) included in the display panel 11a each include the light-emitting element 120a. The display element 21R, the display element 21G, and the display element 21B (not shown) include the coloring layer 152R, the coloring layer 152G, and the coloring layer 152B (not shown), respectively. In the example of FIG. 7A, a light-emitting element emitting white light is used as the light-emitting element 120a. Light emitted from the light-emitting element 120a passes through the coloring layer 152R, the coloring layer 152G, or the coloring layer 152B (not shown), whereby the color light is emitted to the display surface side (the substrate 52a side).

The display element 22R (not shown), the display element 22G (not shown), and the display element 22B included in the display panel 11b each include the light-emitting element 120b. The display element 22R (not shown), the display element 22G (not shown), and the display element 22B include the coloring layer 152R (not shown), the coloring layer 152G (not shown), and the coloring layer 152B, respectively. Light emitted from the light-emitting element 120b passes through the coloring layer 152R (not shown), the coloring layer 152G (not shown), or the coloring layer 152B, whereby the color light is emitted to the display surface side (the substrate 52a side) through the display panel 11a.

FIG. 7B is an enlarged view of the transistor 41a and the transistor 41b, the light-emitting element 120a, and the vicinity thereof in FIG. 7A. Note that the transistor 42a, the transistor 42b, and the light-emitting element 120b can have the structures similar to those of the transistor 41a, the transistor 41b, and the light-emitting element 120a, respectively; thus, their description is skipped and description below is referred to.

The transistor 41a and the transistor 41b are provided over the insulating layer 31. The transistor 41a is connected to the transistor 41b and serves as a pixel-selection transistor. The transistor 41b is connected to the light-emitting element 120a and serves as a driver transistor for controlling current flowing to the light-emitting element 120a.

The transistor 41a includes a conductive layer 111 serving as a gate, an insulating layer 132 serving as a gate insulating layer, a semiconductor layer 112a, a conductive layer 113a serving as one of a source and a drain, and a conductive layer 113b serving as the other of the source and the drain. The transistor 41a shown in FIG. 7B and the like is a channel-etched bottom-gate transistor.

An insulating layer 133 is provided to cover the transistor 41a. The insulating layer 133 serves as a protective layer for protecting the transistor 41a.

The transistor 41b includes a semiconductor layer 112b over the conductive layer 113b with the insulating layer 133 sandwiched therebetween. The transistor 41b also includes a conductive layer 113c and a conductive layer 113d in contact with the semiconductor layer 112b. Part of the conductive layer 113b serves as a gate of the transistor 41b. Part of the insulating layer 133 serves as a gate insulating layer of the transistor 41b. The conductive layer 113c and the conductive layer 113d serve as the source and the drain of the transistor 41b.

As described above, the transistor 41b is provided above the transistor 41b. The conductive layer 113b serves as the other of the source and the drain of the transistor 41a and as the gate of the transistor 41a. The area occupied by the transistors 41a and 41b can be reduced in this structure as compared to a structure in which they are provided side by side on the same plane.

Part of the conductive layer 113d, part of the insulating layer 133, and part of the conductive layer 113b are stacked to form a capacitor 130. The capacitor 130 functions as a storage capacitor of the pixel.

An insulating layer 136 and an insulating layer 134 cover the transistor 41b. The insulating layer 136 serves as a protective layer for protecting the transistor 41b. The insulating layer 134 preferably serves as a planarization film. Note that either one of the insulating layer 136 and the insulating layer 134 is not necessarily provided if not needed.

A conductive layer 121 is provided over the insulating layer 134. The conductive layer 121 is electrically connected to the conductive layer 113d through an opening provided in the insulating layers 134 and 136. In addition, an insulating layer 135 covers the end portion of the conductive layer 121 and the opening. An EL layer 122 and a conductive layer 123 are stacked over the insulating layer 135 and the conductive layer 121. In the example of FIG. 7B, an optical adjustment layer 125 is provided between the conductive layer 121 and the EL layer 122. The conductive layer 121 serves as a pixel electrode of the light-emitting element 120a.

The conductive layer 123 serves as a common electrode. The EL layer 122 includes at least a light-emitting layer.

The light-emitting element 120a is a top-emission light-emitting element which emits light to the side opposite to the formation surface side. A conductive film that reflects visible light can be used as the conductive layer 121. A conductive film that transmits visible light can be used as the conductive layer 123.

In the example of FIGS. 7A and 7B, the light-emitting elements 120a having the same structure are used as display elements showing different colors. In this example, the light-emitting elements 120a are light-emitting elements emitting white light.

The EL layer 122 included in the light-emitting elements 120a is shared by the display elements showing different colors. Thus, the formation process can be simplified as compared to when the EL layers 122 are separately formed. As compared to when the EL layers 122 are formed separately for the display elements showing different colors, the distance between adjacent pixels can be further reduced and the resolution can be increased because there is no need to consider design rules, which is defined by the minimum processing dimension, alignment accuracy, and the like for formation of the EL layers 122.

Note that the light-emitting element 120a may have a microcavity (micro resonator) structure using a semi-transmissive and semi-reflective conductive film as the conductive layer 123. In the structure, the optical adjustment layer 125 that transmits visible light may be provided to adjust the optical distance between the conductive layer 121 and the conductive layer 123. The thickness of the optical adjustment layer 125 preferably differs between the display elements showing different colors.

The combination of the EL layer 122 emitting white light, the microcavity structure, and the coloring layer makes it possible to emit light with extremely high color purity toward the display surface side.

FIG. 7C is a circuit diagram corresponding to the structure shown in FIG. 7B. FIG. 7C is a circuit diagram of each pixel (subpixel).

For example, a gate (the conductive layer 111) of the transistor 41a is electrically connected to a wiring to which a gate signal VG is applied. One of the source and the drain (the conductive layer 113a) of the transistor 41a is electrically connected to a wiring to which a source signal VS is applied. One of the source and the drain (the conductive layer 113c) of the transistor 41b is electrically connected to a wiring to which a potential VH is applied. The common electrode (the conductive layer 123) of the light-emitting element 120a is electrically connected to a wiring to which a potential VL is applied.

Note that the structure of the pixel is not limited thereto and a variety of circuit configurations can be used.

A region through which light from the display panel 11b side passes is provided between two adjacent display elements showing different colors in the display panel 11a (e.g., the display element 21R and the display element 21G). Thus, mixture of colors that might occur when light emitted from the light-emitting element 120a of one display element (e.g., the display element 21R) passes through a coloring layer (the coloring layer 152G) of the other display element (e.g., the display element 21G) is unlikely to occur. For this reason, high-quality display can be performed without a light-blocking layer for suppressing mixture of colors between adjacent pixels.

Light emitted in an oblique direction from the light-emitting element 120b on the display panel 11b side is blocked by the conductive layer 121 of the light-emitting element 120a on the display panel 11a side, conductive layers included in the transistor 41a and 41b, wirings, and the like. Owing to the structure, mixture of colors that might occur when light emitted from the light-emitting element 120b on the display panel 11b side passes through the coloring layer provided on the display panel 11a side is unlikely to occur.

The above is the description of the cross-sectional structure example 1-1.

### CROSS-SECTIONAL STRUCTURE EXAMPLE 1-2

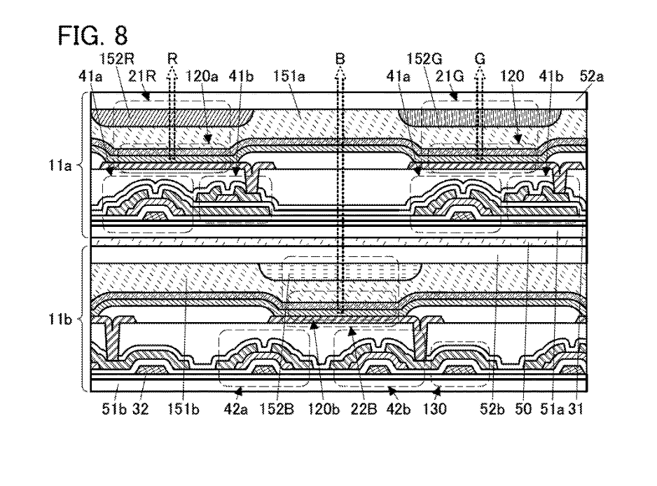

FIG. 8 is a schematic cross-sectional view of a display device described below as an example. The structure of the display panel 11b is different between FIG. 8 and FIG. 7A.

In the display panel 11b in FIG. 8, the transistor 42a and the transistor 42b are positioned side by side over the insulating layer 32. In addition, the capacitor 130 is provided over the insulating layer 32.

The transistor 42a and the transistor 42b have the same structure as the transistor 41a shown in FIGS. 7A and 7B.

The capacitor 130 includes a conductive layer which is formed by processing the same conductive film as the gates of the transistors, one part of the insulating layer whose another part serves as a gate insulating layer of the transistor, and a conductive layer formed by processing the same conductive film as the source and the drain of the transistor.

Even when the area occupied by each of the transistor 42a, the transistor 42b, the capacitor 130, and the like is large, it does not have influence on the aperture ratio and resolution of the display device because they are positioned below the light-emitting element 120b in the drawing. Thus, they can be provided side by side, and the fabrication process can be simplified.

The above is the description of the cross-sectional structure example 1-2.

### CROSS-SECTIONAL STRUCTURE EXAMPLE 1-3

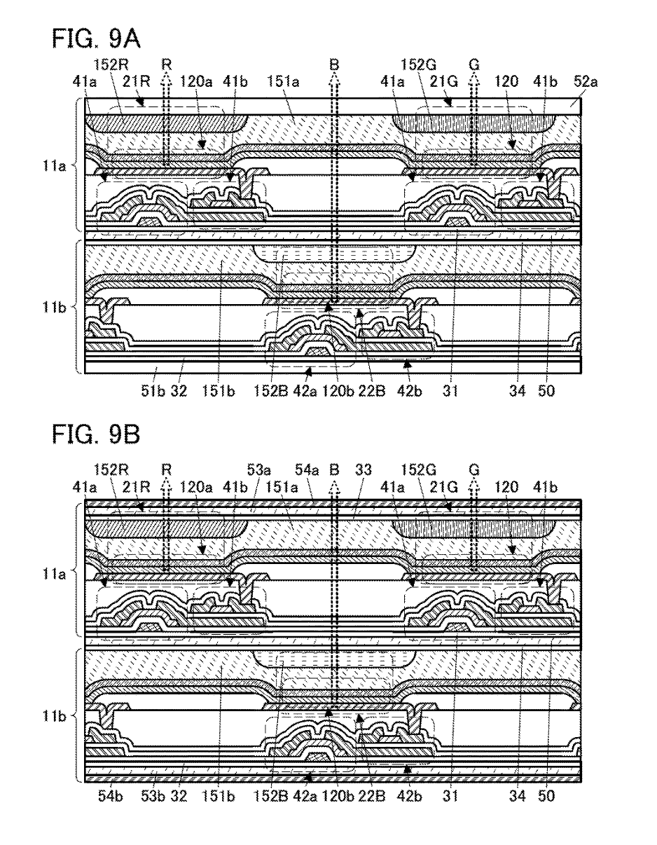

FIG. 9A is a schematic cross-sectional view of a display device described below as an example. The structure shown in FIG. 9A is mainly different from the structure shown in FIG. 7A in that the substrate 51a and the substrate 52b are not included.

The structure shown in FIG. 9A includes an insulating layer 34 instead of the substrate 52b. The coloring layer 152B is formed on one surface of the insulating layer 34, and the adhesive layer 50 is in contact with the other surface of the insulating layer 34. The insulating layer 34 is bonded to the insulating layer 31 with the adhesive layer 50.

Since the substrate 51a and the substrate 52b are not included, the display device can be reduced in weight and thickness. In addition, since the substrate 51a and the substrate 52b are not included, the light-emitting element 120b can be provided closer to the display surface.

This can improve the viewing angle characteristics on the display panel 11b side.

It is preferable that the insulating layer 34 not only support the coloring layer 152B and the like but also serve as a protective layer for preventing diffusion of impurities such as water from the adhesive layer 50 and the like to the light-emitting element 120b.

The structure not including the substrates can be fabricated in the following manner. For example, a separation layer is formed over a support substrate. An insulating layer, a transistor, a coloring layer, and the like are formed over the separation layer. Then, the separation layer is separated from the insulating layer and the like (alternatively, the separation layer is separated from part of the separation layer, or from the substrate), whereby the substrate can be removed. If the separation layer which is in contact with the insulating layer remains, it may be removed or left. The description below can be referred to for the separation layer.

For example, in the case of the example shown in FIG. 9A, the separation layer and the insulating layer 31 are stacked over the support substrate. Then, the transistor 41a, the transistor 41b, the light-emitting element 120a, and the like are formed. The substrate 52a is bonded using the adhesive layer 151a to form the display panel 11a. Then, the support substrate is removed. Next, another separation layer and the insulating layer 34 are stacked over another support substrate, and the coloring layer 152B and the like are formed over the insulating layer 34. The substrate 51b where the transistor 42a, the transistor 42b, the light-emitting element 120b, and the like are formed is bonded to the support substrate using the adhesive layer 151b, and the support substrate is removed. Then, the insulating layer 31 is bonded to the insulating layer 34 using the adhesive layer 50 to complete the display device shown in FIG. 9A.

The above is the description of the cross-sectional structure example 1-3.

### CROSS-SECTIONAL STRUCTURE EXAMPLE 1-4

FIG. 9B is a schematic cross-sectional view of a display device described below as an example. The structure shown in FIG. 9B is different from the structure shown in FIG. 9A in that a substrate 54a and a substrate 54b are included instead of the substrate 52a and the substrate 51b. A material thinner or lighter than the material of the substrate 52a can be used for the substrate 54a. A material thinner or lighter than the material of the substrate 51b can be used for the substrate 54b.

In the display panel 11a, an insulating layer 33, an adhesive layer 53a, and the substrate 54a are stacked over the coloring layer 152R. In the display panel 11b, the substrate 54b, an adhesive layer 53b, and the insulating layer 32 are stacked.

Such a structure can achieve an extremely lightweight display device. In addition, the use of a flexible material for the substrate 54a and the substrate 54b can achieve a display device which can be bent.

The above is the description of the cross-sectional structure example 1-4.

### CROSS-SECTIONAL STRUCTURE EXAMPLE 1-5

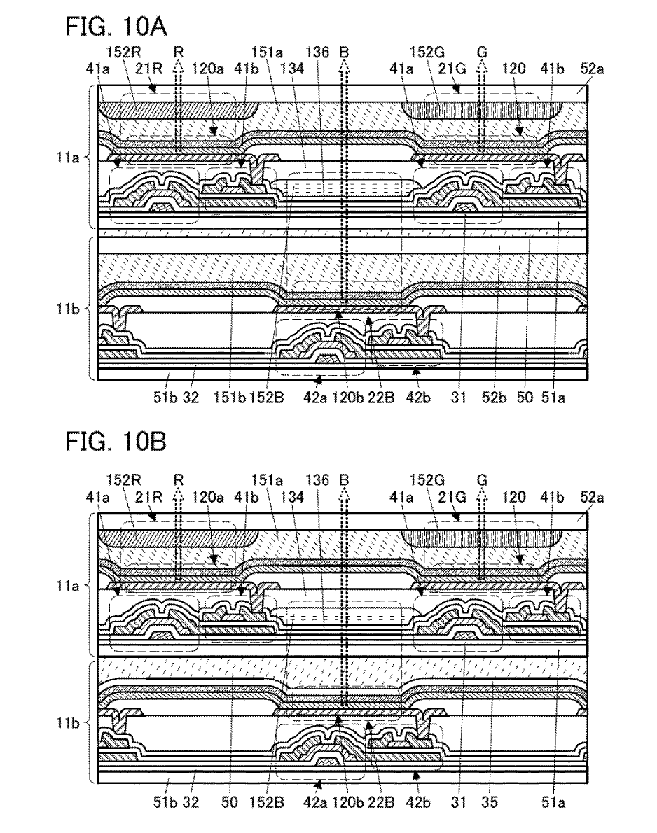

FIG. 10A is a schematic cross-sectional view of a display device described below as an example. The structure shown in FIG. 10A is different from the structure shown in FIG. 7A in the position of the coloring layer 152B and the like.

In the structure shown in FIG. 10A, the coloring layer 152B is provided not on the display panel 11b side but on the display panel 11a side. Specifically, the coloring layer 152B is provided between the insulating layer 136 covering the transistor 41b and the insulating layer 134 serving as a planarization layer.

Light emitted from the light-emitting element 120b passes through the coloring layer 152B provided on the display panel 11a side and is extracted to the display surface side. The structure does not need formation of the coloring layer 152B and the like over the substrate 52b and thus can be simplified.

### MODIFICATION EXAMPLE 1-1

A structure without the substrate 52b as shown in FIG. 10B may be used.

In the example of FIG. 10B, an insulating layer 35 covers the light-emitting element 120b. The insulating layer 35 serves as a protective layer for preventing diffusion of impurities such as water into the light-emitting element 120b.

In FIG. 10B, the adhesive layer 151b is not included, and the insulating layer 35 is bonded to the substrate 51a with the adhesive layer 50.

Such a structure can achieve a lightweight and thin display device.

### MODIFICATION EXAMPLE 1-2

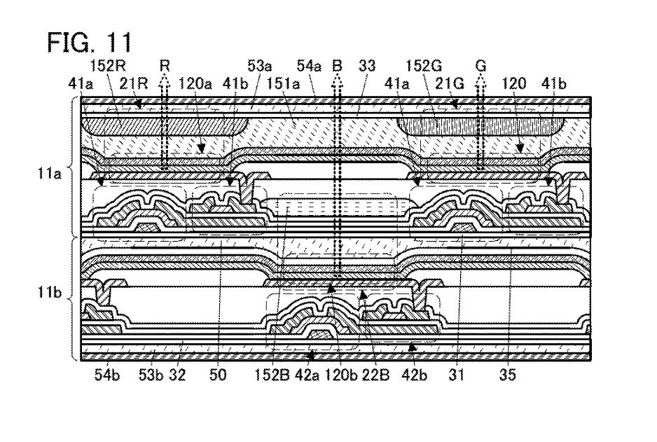

FIG. 11 shows an example of the coloring layer 152B and the like shown in FIG. 10B and the flexible substrates 54a and 54b shown in the example of FIG. 9B.

In FIG. 11, the insulating layer 35 is bonded to the insulating layer 31 with the adhesive layer 50.

The above is the description of the cross-sectional structure example 1-5.

### CROSS-SECTIONAL STRUCTURE EXAMPLE 1-6

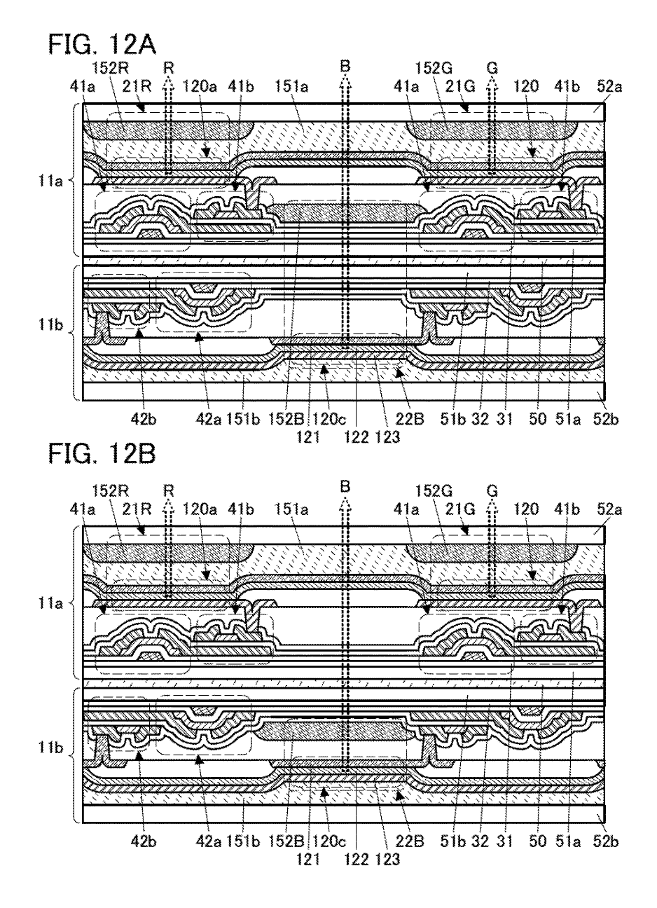

FIG. 12A is a schematic cross-sectional view of a display device described below as an example. The structure shown in FIG. 12A is mainly different from the structure shown in FIG. 7A in that a bottom emission light-emitting element 120c is used for the display panel 11b.

The structure of the display panel 11b is substantially the same as the upside-down structure of the display panel 11b shown in FIG. 7A except the below-described points. Thus, in the display panel 11b, the substrate 51b is positioned on the display surface side and is bonded to the substrate 51a with the adhesive layer 50.

In the light-emitting element 120c, a conductive film transmitting visible light and a conductive film reflecting visible light are used as the conductive layer 121 positioned on the viewer's side and the conductive layer 123 positioned on the side opposite to the viewer's side, respectively.

Here, it is important not to provide the transistor 42a, the transistor 42b, and the like on a path of light emitted from the light-emitting element 120c because the light-emitting element 120c is a bottom emission light-emitting element. It is preferable that the light-emitting element 120c and the transistor 42a or the transistor 42b be positioned not to overlap with each other. When the transistor 42a partly overlaps with the transistor 42b as shown in FIG. 12A, the aperture ratio of the display panel 11b can be increased.

Although the coloring layer 152B and the like are provided in the display panel 11a in the example of FIG. 12A, the coloring layer 152B may be provided in the display panel 11b as shown in FIG. 12B.

The above is the description of the cross-sectional structure example 1-6.

Note that the components shown in the drawings can be interchanged or combined with each other as appropriate. The above is the description of the cross-sectional structure example 1.

### CROSS-SECTIONAL STRUCTURE EXAMPLE 2 OF DISPLAY DEVICE

This structure example will show a structure example in which display elements showing different colors include different light-emitting layers (EL layers).

Note that some portions similar to those described in the cross-sectional structure example 1 of the display device are not described here.

### CROSS-SECTIONAL STRUCTURE EXAMPLE 2-1

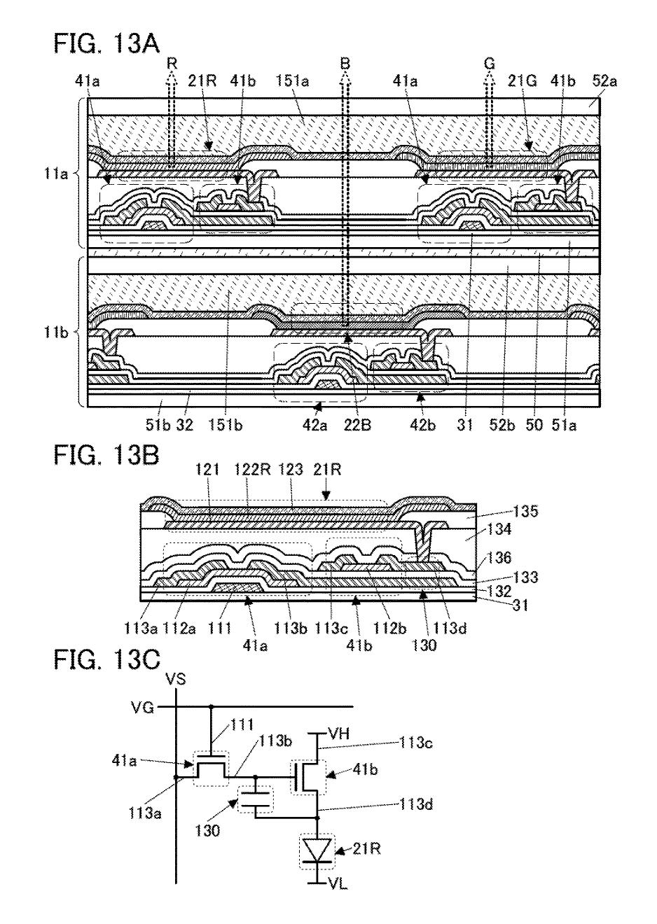

FIG. 13A is a schematic cross-sectional view of a display portion of the display device 10.

The display panel 11a includes the transistor 41a, the transistor 41b, the display element 21R, the display element 21G, the display element 21B (not shown), the adhesive layer 151a, and the like between the substrate 51a and the substrate 52a. The substrate 51a and the substrate 52a are bonded to each other with the adhesive layer 151a. The transistor 41a, the transistor 41b, the display element 21R, and the like are provided over the insulating layer 31.

The display panel 11b includes the transistor 42a, the transistor 42b, the display element 22R (not shown), the display element 22G (not shown), the display element 22B, the adhesive layer 151b, and the like between the substrate 51b and the substrate 52b. The substrate 51b and the substrate 52b are bonded to each other with the adhesive layer 151b. The transistor 42a, the transistor 42b, the display element 22B, and the like are provided over the insulating layer 32.

The display element 21R, the display element 21G, and the display element 21B (not shown) which are included in the display panel 11a include light-emitting elements showing different colors and emit light to the substrate 52a side (the display surface side).

The display element 22R (not shown), the display element 22G (not shown), and the display element 22B which are included in the display panel 11b include light-emitting elements showing different colors and emit light to the substrate 52a side (the display surface side) through the display panel 11a.

FIG. 13B is an enlarged view of the transistor 41a and the transistor 41b, the display element 21R, and the vicinity thereof in FIG. 13A. Note that the transistor 42a, the transistor 42b, and the display element 21B can have the structures similar to those of the transistor 41a, the transistor 41b, and the display element 21R, respectively; thus, their description is skipped and description below is referred to.

The transistor 41a and the transistor 41b are provided over the insulating layer 31. The transistor 41a is connected to the transistor 41b and serves as a pixel-selection transistor. The transistor 41b is connected to the display element 21R and serves as a driver transistor for controlling current flowing to the display element 21R.

The conductive layer 121 serves as a pixel electrode of the display element 21R. The conductive layer 123 serves as a common electrode. The EL layer 122R includes at least a light-emitting layer.

The display element 21R is a top-emission light-emitting element which emits light to the side opposite to the formation surface side. A conductive film that reflects visible light can be used as the conductive layer 121. A conductive film that transmits visible light can be used as the conductive layer 123.

FIGS. 13A and 13B show an example in which EL layers are formed separately for display elements showing different colors. The EL layers of the display elements include light-emitting layers showing different colors.

The EL layer 122R included in the display element 21R includes a light-emitting layer emitting red color, for example. When the EL layers are formed separately for display elements showing different colors like this, the color purity of light emitted from the display elements can be increased. In addition, light extraction efficiency can be increased as compared to when a coloring layer (color filter) or the like is used. Furthermore, driving voltage can be reduced as compared to when, for example, a plurality of light-emitting layers is stacked and a light-emitting element emitting white light is used.

Here, the structure of a light-emitting element which can be used for the display element 21R, the display element 21G, the display element 21B, and the like is described. Note that the structure described below can be employed in the display element 22R, the display element 22G, and the display element 22B.

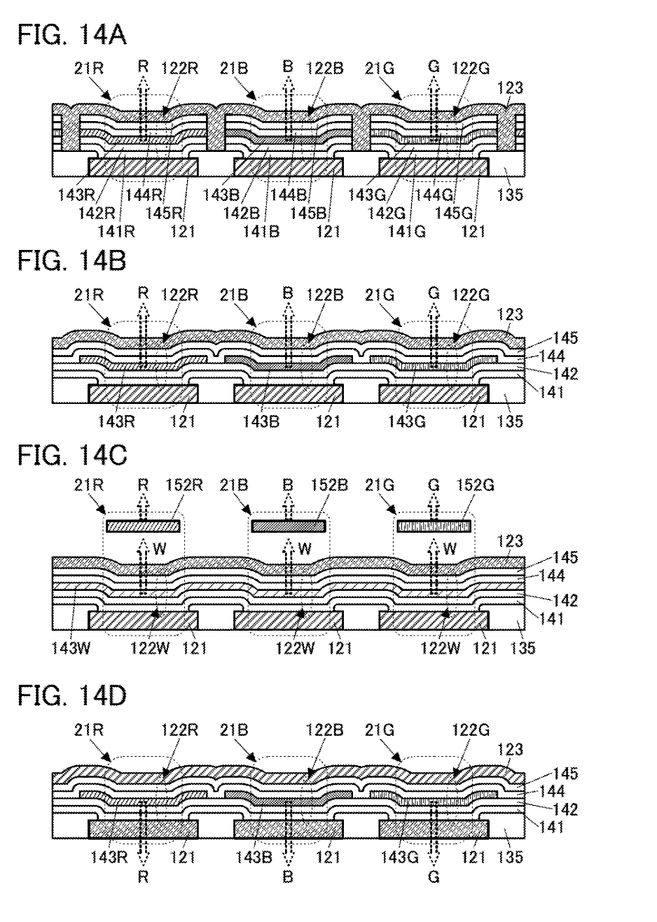

FIG. 14A shows an example in which all layers forming the EL layers are formed separately for display elements showing different colors.

The display element 21R includes the EL layer 122R between the conductive layer 121 and the conductive layer 123. In FIG. 14A, the EL layer 122R includes a carrier-injection layer 141R, a carrier-transport layer 142R, a light-emitting layer 143R, a carrier-transport layer 144R, and a carrier-injection layer 145R (listed in the order from the conductive layer 121 side).

For example, when the conductive layer 121 and the conductive layer 123 serve as an anode and a cathode, respectively, a material having high hole-injection properties is used for the carrier-injection layer 141R, a material having high hole-transport properties is used for the carrier-transport layer 142R, a material having high electron-transport properties is used for the carrier-transport layer 144R, and a material having high electron-injection properties is used for the carrier-injection layer 145R. Note that in the case where the anode and the cathode are interchanged, the order of the layers therebetween can be changed.

Similarly, the EL layer 122B of the display element 21B includes a carrier-injection layer 141B, a carrier-transport layer 142B, a light-emitting layer 143B, a carrier-transport layer 144B, and a carrier-injection layer 145B. The EL layer 122G of the display element 21G includes a carrier-injection layer 141G, a carrier-transport layer 142G, a light-emitting layer 143G, a carrier-transport layer 144G, and a carrier-injection layer 145G.

In the above structure in which the EL layer 122R, the EL layer 122B, and the EL layer 122G are formed independently, the element structure in which each of the display elements is optimized can be obtained. For example, layers of different materials can be used as the EL layer 122R, the EL layer 122B, and the EL layer 122G. Owing to this, the color purity, emission efficiency, light extraction efficiency, and the like can be extremely high.

Although, in the drawing, the thickness of the layers included in the EL layers is substantially the same between the display elements, the thickness of the layers may be different from each other.

FIG. 14B shows an example in which only light-emitting layers are formed separately for display elements and other layers are shared by the display elements.

The carrier-injection layer 141, the carrier-transport layer 142, the carrier-transport layer 144, and the carrier-injection layer 145 are shared by the display elements.

With such a structure, the fabrication process can be simplified.

Note that one or more of the carrier-injection layer 141, the carrier-transport layer 142, the carrier-transport layer 144, and the carrier-injection layer 145 may be separately formed.

In the case where both a display element in which a phosphorescent light-emitting material is used for its light-emitting layer and a display element in which a fluorescent light-emitting material is used for its light-emitting layer are included, it is preferable that layers not shared therebetween be formed separately and other layers be shared by the display elements.

FIG. 14C shows an example in which the same-structure EL layer is used for the display elements showing different colors. Specifically, the example shows a structure in which an EL layer 122W emitting white light is combined with coloring layers of display elements to emit light of different colors.

The display element 21R, the display element 21B, and the display element 21G include the coloring layer 152R, the coloring layer 152B, and the coloring layer 152G, respectively.

The EL layer 122W included in each of the display element 21R, the display element 21B, and the display element 21G is shared by the different display elements. Thus, the formation process can be simplified as compared to when the EL layers are separately formed. As compared to when the EL layers are formed separately for the display elements showing different colors, the distance between adjacent pixels can be further reduced and the resolution can be increased because there is no need to consider design rules, which is defined by the minimum processing dimension, alignment accuracy, and the like for formation of the EL layers 122W.

Note that a microcavity (micro resonator) structure may be employed using a semi-transmissive and semi-reflective conductive film as the conductive layer 123. In the structure, an optical adjustment layer that transmits visible light may be provided to adjust the optical distance between the conductive layer 121 and the conductive layer 123. The thickness of the optical adjustment layer preferably differs between the display elements showing different colors.

The combination of the EL layer 122 emitting white light, the microcavity structure, and the coloring layer makes it possible to emit light with extremely high color purity toward the display surface side.

FIG. 14D shows an example using a bottom emission display element emitting light toward the formation surface side. In the example, only light-emitting layers are formed separately for display elements as in FIG. 14B.

In FIG. 14D, a conductive film that transmits visible light and a conductive film that reflects visible light are used as the conductive layer 121 and the conductive layer 123, respectively. With this structure, the display element 21R, the display element 21B, and the display element 21G emit light to the conductive layer 121 side.

The above is the description of the structure example of the light-emitting element.

FIG. 13C is a circuit diagram corresponding to the structure shown in FIG. 13B. FIG. 13C is a circuit diagram of each pixel (subpixel).

For example, a gate (the conductive layer 111) of the transistor 41a is electrically connected to a wiring to which a gate signal VG is applied. One of the source and the drain (the conductive layer 113a) of the transistor 41a is electrically connected to a wiring to which a source signal VS is applied. One of the source and the drain (the conductive layer 113c) of the transistor 41b is electrically connected to a wiring to which a potential VH is applied. The common electrode (the conductive layer 123) of the display element 21R is electrically connected to a wiring to which a potential VL is applied.

Note that the structure of the pixel is not limited thereto and a variety of circuit configurations can be used.

A region through which light from the display panel 11b side passes is provided between two adjacent display elements showing different colors in the display panel 11a (e.g., the display element 21R and the display element 21G). Thus, mixture of colors that might occur when light emitted from one display element (e.g., the display element 21R) passes through the other display element (e.g., the display element 21G) is unlikely to occur. For this reason, high-quality display can be performed without a light-blocking layer for suppressing mixture of colors between adjacent pixels.

Light emitted in an oblique direction from the display element (e.g., the display element 22B) on the display panel 11b side is blocked by the conductive layer 121 of the display element 21R on the display panel 11a side, conductive layers included in the transistor 41a and 41b, wirings, and the like. Owing to the structure, mixture of colors that might occur when light emitted from the display element 22B and the like on the display panel 11b side passes through the display element 21R and the like provided on the display panel 11a side is unlikely to occur.

The above is the description of the cross-sectional structure example 2-1.

### CROSS-SECTIONAL STRUCTURE EXAMPLE 2-2

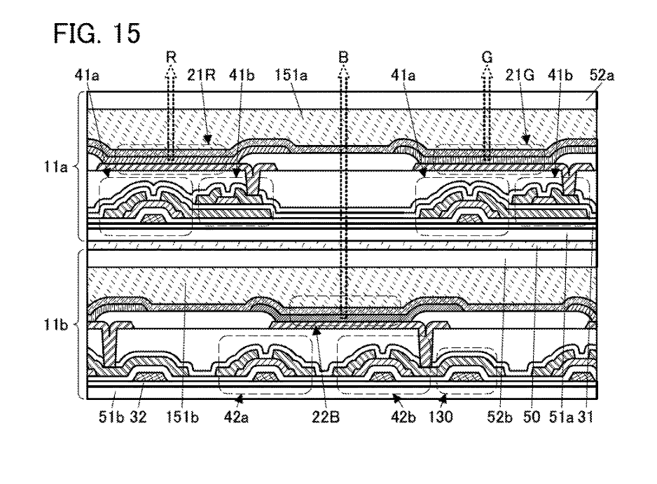

FIG. 15 is a schematic cross-sectional view of a display device described below as an example. The structure of the display panel 11b is different between FIG. 15 and FIG. 13A.

In the display panel 11b in FIG. 15, the transistor 42a and the transistor 42b are positioned side by side over the insulating layer 32. In addition, the capacitor 130 is provided over the insulating layer 32.

The transistor 42a and the transistor 42b have the same structure as the transistor 41a shown in FIGS. 13A and 13B.

The capacitor 130 includes a conductive layer which is formed by processing the same conductive film as the gates of the transistors, the other part of the insulating layer whose part serves as a gate insulating layer of the transistor, and a conductive layer formed by processing the same conductive film as the source and the drain of the transistor.

Even when the area occupied by each of the transistor 42a, the transistor 42b, the capacitor 130, and the like is large, it does not have influence on the aperture ratio and resolution of the display device because they are positioned below the display element 22B in the drawing. Thus, they can be provided side by side, and the fabrication process can be simplified.

The above is the description of the cross-sectional structure example 2-2.

### CROSS-SECTIONAL STRUCTURE EXAMPLE 2-3

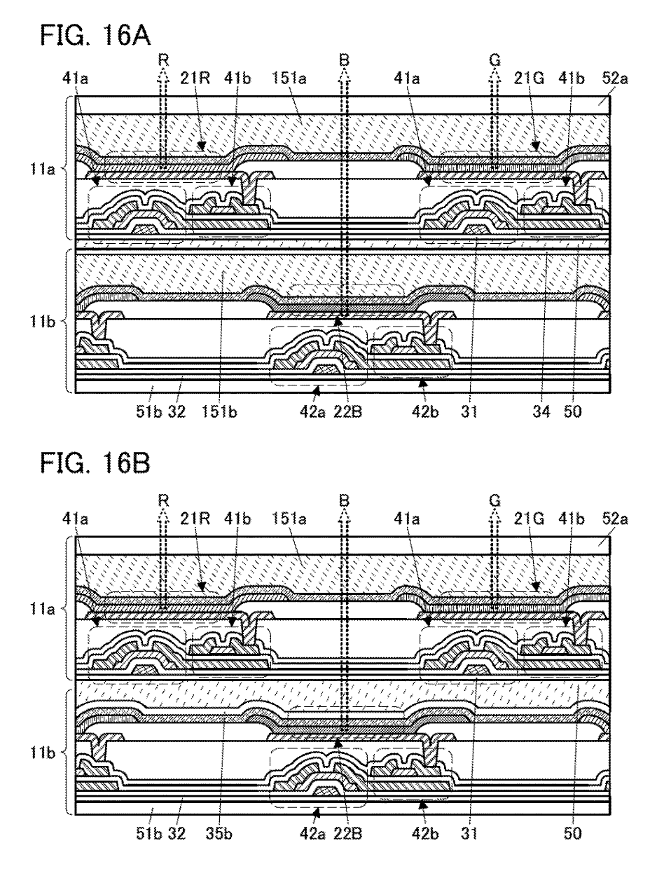

FIG. 16A is a schematic cross-sectional view of a display device described below as an example. The structure shown in FIG. 16A is mainly different from the structure shown in FIG. 13A in that the substrate 51a and the substrate 52b are not included.

The structure shown in FIG. 16A includes an insulating layer 34 instead of the substrate 52b. One surface of the insulating layer 34 is in contact with the adhesive layer 151b, and the other surface thereof is in contact with the adhesive layer 50. The insulating layer 34 is bonded to the insulating layer 31 with the adhesive layer 50.

Since the substrate 51a and the substrate 52b are not included, the display device can be reduced in weight and thickness. In addition, since the substrate 51a and the substrate 52b are not included, the display element 22B can be provided closer to the display surface. This can improve the viewing angle characteristics on the display panel 11b side.

It is preferable that the insulating layer 34 serves as a protective layer for preventing diffusion of impurities such as water from the adhesive layer 50 and the like to the display element 22B.

For example, in the case of the example shown in FIG. 16A, the separation layer and the insulating layer 31 are stacked over the support substrate. Then, the transistor 41a, the transistor 41b, the display element 21R, and the like are formed. The substrate 52a is bonded using the adhesive layer 151a to form the display panel 11a. Then, the support substrate is removed. Next, another separation layer and the insulating layer 34 are stacked over another support substrate. The substrate 51b where the transistor 42a, the transistor 42b, the display element 22B, and the like are formed is bonded to the support substrate using the adhesive layer 151b, and the support substrate is removed. Then, the insulating layer 31 is bonded to the insulating layer 34 using the adhesive layer 50 to complete the display device shown in FIG. 16A.

The above is the description of the cross-sectional structure example 2-3.

### MODIFICATION EXAMPLE 2-1

FIG. 16B shows an example not including the insulating layer 34 shown in FIG. 16A.

In the example of FIG. 16B, an insulating layer 35b covers the display element 22B and the like. The insulating layer 35b serves as a protective layer for preventing diffusion of impurities such as water into the display element 22B and the like.

In FIG. 16B, the adhesive layer 151b is not included, and the insulating layer 35b is bonded to the insulating layer 31 with the adhesive layer 50.

Such a structure can achieve a lightweight and thin display device.

### CROSS-SECTIONAL STRUCTURE EXAMPLE 2-4

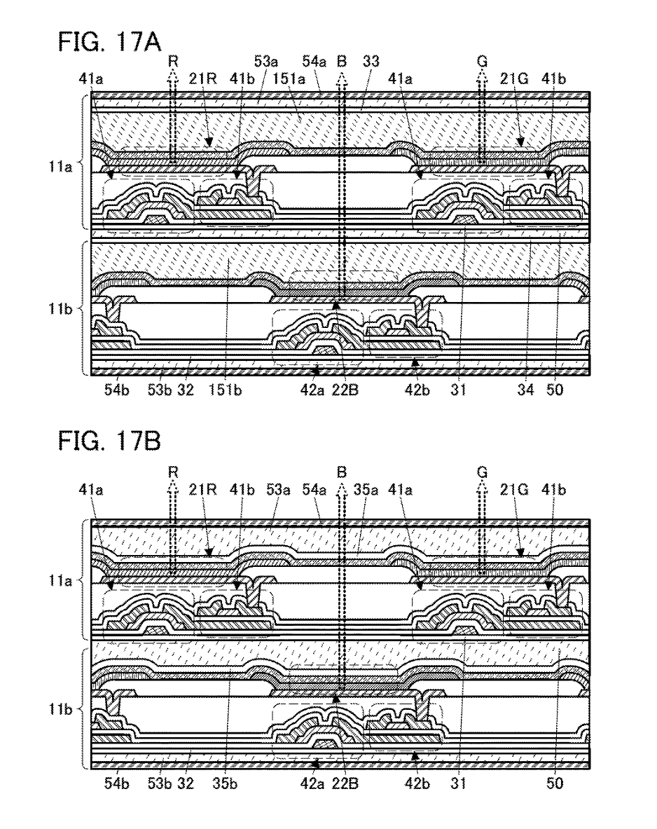

FIG. 17B is a schematic cross-sectional view of a display device described below as an example. The structure shown in FIG. 17B is different from the structure shown in FIG. 16A in that a substrate 54a and a substrate 54b are included instead of the substrate 52a and the substrate 51b. A material thinner or lighter than the material of the substrate 52a can be used for the substrate 54a. A material thinner or lighter than the material of the substrate 51b can be used for the substrate 54b.

In the display panel 11a, the insulating layer 33, the adhesive layer 53a, and the substrate 54a are stacked in this order from the inner side. In the display panel 11b, the substrate 54b, the adhesive layer 53b, and the insulating layer 32 are stacked (listed in the order from the bottom of the drawing).

Such a structure can achieve an extremely lightweight display device. In addition, the use of a flexible material for the substrate 54a and the substrate 54b can achieve a display device which can be bent.

The above is the description of the cross-sectional structure example 2-4.

### MODIFICATION EXAMPLE 2-2

FIG. 17B shows an example without the insulating layer 34 and the insulating layer 33 which are shown in FIG. 17A.

An insulating layer 35a covering the display element 21R and the like and an insulating layer 35b covering the display element 22B and the like are provided.

In FIG. 17B, the adhesive layer 151a is not provided, and the substrate 54a and the insulating layer 35a are bonded with the adhesive layer 53a. Similarly, the adhesive layer 151b is not provided, and the insulating layer 35b and the insulating layer 31 are bonded with the adhesive layer 50.

Owing to the structure, the thickness of the display device can be further reduced without lowering the reliability.

### CROSS-SECTIONAL STRUCTURE EXAMPLE 2-5

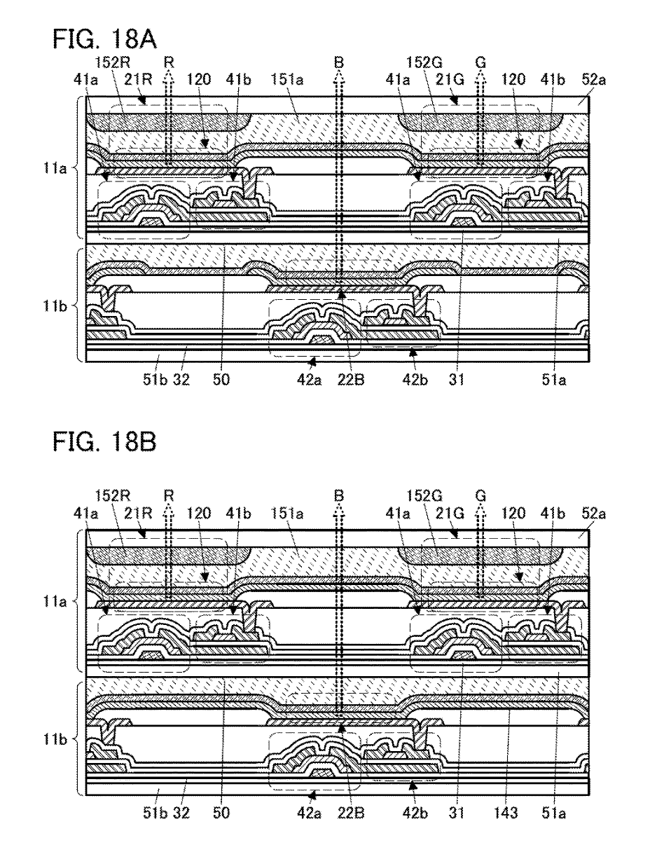

FIG. 18A is a schematic cross-sectional view of a display device described below as an example. The structure shown in FIG. 18A is mainly different from the structure shown in FIG. 13A in the structure of the display element included in the display panel 11a, and the like.

The display element 21R of the display panel 11a includes a light-emitting element 120 and the coloring layer 152R. Similarly, the display element 21G includes the light-emitting element 120 and the coloring layer 152G. The display element 21B (not shown) includes the light-emitting element 120 and the coloring layer 152B (not shown). The coloring layer 152R, the coloring layer 152G, and the coloring layer 152B (not shown) overlap with the light-emitting elements 120. In the example here, a light-emitting element emitting white light is used as the light-emitting element 120. Light emitted from the light-emitting element 120 of the display element 21R passes through the coloring layer 152R, whereby the color light is emitted to the display surface side (the substrate 52a side). In a similar manner, light emitted from the display element 21G and the display element 21B (not shown) pass through the coloring layer 152G and the coloring layer 152B (not shown), respectively, whereby the color light is emitted to the display surface side.

Light emitted in an oblique direction from the display element (e.g., the display element 22B) on the display panel 11b side is blocked by the conductive layer 121 of the display element 21R on the display panel 11a side, conductive layers included in the transistor 41a and 41b, wirings, and the like. Owing to the structure, mixture of colors that might occur when light emitted from the display element 22B and the like on the display panel 11b side passes through the coloring layer provided on the display panel 11a side is unlikely to occur.

In addition, the substrate 52b is not provided in the example shown in FIG. 18A. The adhesive layer 50 bonds the substrate 51a to the display element 22B and the like. The structure can achieve a thinner and lighter display device.

The above is the description of the cross-sectional structure example 2-5.

### MODIFICATION EXAMPLE 2-3

FIG. 18B shows an example in which EL layers are not separately formed for a plurality of display elements included in the display panel 11b.

For example, two kinds of display elements, red (R) and green (G), are alternately provided in the display panel 11a, and only blue (B) display elements are periodically provided in the display panel 11b. In the structure, there is no need to separately form EL layers on the display panel 11b side, and thus the fabrication process can be simplified.

In addition, in the structure, the distance between two display elements showing different colors in the display panel 11a can be reduced. This can achieve a higher-resolution display device.

Note that such a structure may be used that three kinds of display elements, red (R), green (G), and blue (B), are provided on the display panel 11a side and any one kind of them is provided on the display panel 11b side. A display element emitting color other than red (R), green (G), and blue (B), such as white (W) or yellow (Y) may be provided.

In the cross-sectional structure example 2-5 and the modification example 2-3, a display element including a coloring layer and a light-emitting element is used for the display panel 11a, and a display element without a coloring layer is used for the display panel 11b; however, they may be interchanged. In other words, the display element without a coloring layer may be used for the display panel 11a and the display element including a coloring layer and a light-emitting element may be used for the display panel 11b.

### CROSS-SECTIONAL STRUCTURE EXAMPLE 2-6

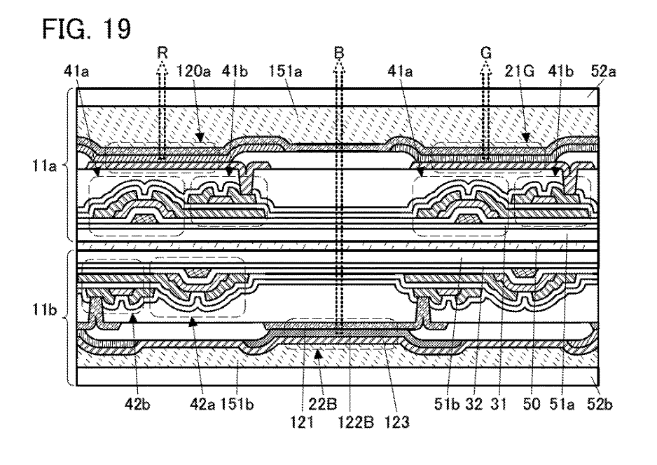

FIG. 19A is a schematic cross-sectional view of a display device described below as an example. The structure shown in FIG. 19A is mainly different from the structure shown in FIG. 13A in that a bottom emission display element 22B and the like are used for the display panel 11b.

The structure of the display panel 11b is substantially the same as the upside-down structure of the display panel 11b shown in FIG. 13A except the below-described points. Thus, in the display panel 11b, the substrate 51b is positioned on the display surface side and is bonded to the substrate 51a with the adhesive layer 50.

In the display element 22B and the like, a conductive film transmitting visible light and a conductive film reflecting visible light are used as the conductive layer 121 positioned on the viewer's side and the conductive layer 123 positioned on the side opposite to the viewer's side, respectively.

Here, it is important not to provide the transistor 42a, the transistor 42b, and the like on a path of light emitted from the display element 22B and the like because the display element 22B and the like are bottom emission light-emitting elements. It is preferable that the display element 22B and the like be positioned not to overlap with the transistor 42a or the transistor 42b. When the transistor 42a partly overlaps with the transistor 42b as shown in FIG. 19, the aperture ratio of the display panel 11b can be increased.

The above is the description of the cross-sectional structure example 2-6.

Note that the components shown in the drawings can be interchanged or combined with each other as appropriate.

The above is the description of the cross-sectional structure example 2.

### EXAMPLE OF STACKED-LAYER STRUCTURE OF TRANSISTORS

Described below are other structure examples in which two transistors are stacked. The below-described structure examples can be combined as appropriate with the above-described cross-sectional structure examples of the display device.

### STRUCTURE EXAMPLE 1

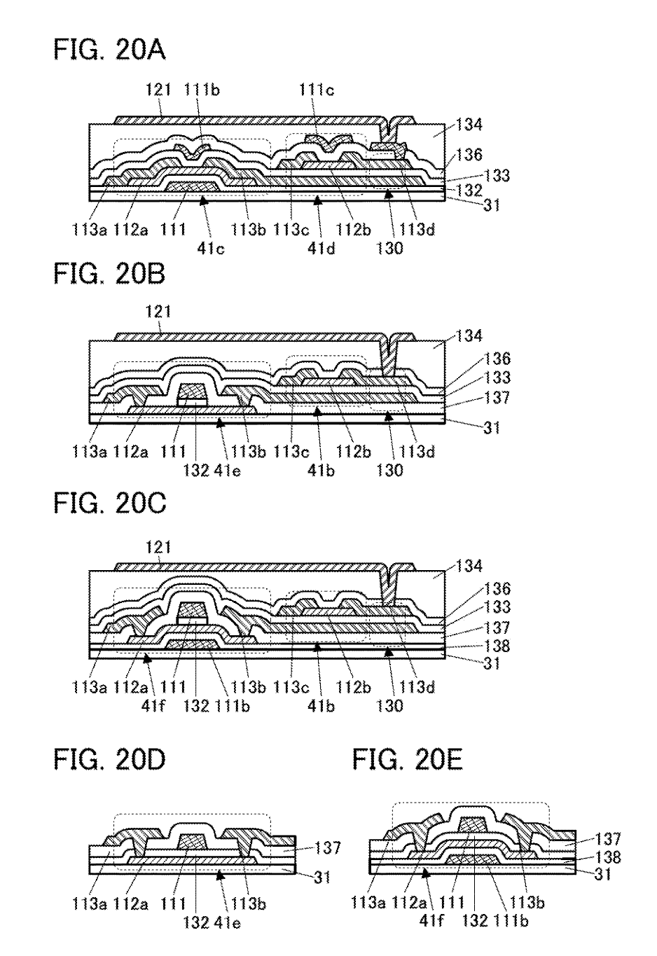

FIG. 20A shows an example in which a transistor 41c is stacked with a transistor 41d.

The transistor 41c corresponds to the transistor 41a shown in FIG. 7B further including a conductive layer 111b serving as a second gate. The conductive layer 111b overlaps with the semiconductor layer 112a and is positioned between the insulating layer 133 and the insulating layer 136.

The transistor 41d corresponds to the transistor 41b shown in FIG. 7B further including the conductive layer 111c serving as a second gate. The conductive layer 111c overlaps with the semiconductor layer 112b and is positioned over the insulating layer 136.

When a transistor includes two gates between which a semiconductor layer is sandwiched, the on-state current of the transistor can be increased by supplying the same potential to the two gates. When a potential for controlling the threshold voltage is supplied to one of the gates and a potential for driving the transistor to the other gate, the threshold voltage of the transistor can be controlled.

### STRUCTURE EXAMPLE 2

FIG. 20B shows an example in which a transistor 41e is stacked with the transistor 41b.

The transistor 41e is a top-gate transistor whose gate is positioned over the semiconductor layer 112a.

The transistor 41e includes the semiconductor layer 112a over the insulating layer 31, the insulating layer 132 over the semiconductor layer 112a, the conductive layer 111 over the insulating layer 132, an insulating layer 137 covering the semiconductor layer 112a and the conductive layer 111, and the conductive layer 113a and the conductive layer 113b over the insulating layer 137.

The transistor 41e is preferable because a parasitic capacitance between the semiconductor layer 112a and the conductive layer 113a or the conductive layer 113b and a parasitic capacitance between the conductive layer 111 and the conductive layer 113a or the conductive layer 113b can be reduced.

Although the insulating layer 132 is formed only in the portion overlapping with the conductive layer 111 in the example of FIG. 20B, the insulating layer 132 may cover the end portion of the semiconductor layer 112a as shown in FIG. 20D.

### STRUCTURE EXAMPLE 3

FIG. 20C shows an example in which a transistor 41f is stacked with the transistor 41b.

The transistor 41f corresponds to the transistor 41e further including the conductive layer 111b serving as a second gate. The conductive layer 111b overlaps with the semiconductor layer 112a with an insulating layer 138 provided therebetween.

Although the insulating layer 132 is formed only in the portion overlapping with the conductive layer 111 in the example of FIG. 20C, the insulating layer 132 may cover the end portion of the semiconductor layer 112a as shown in FIG. 20E.

### STRUCTURE EXAMPLE 4

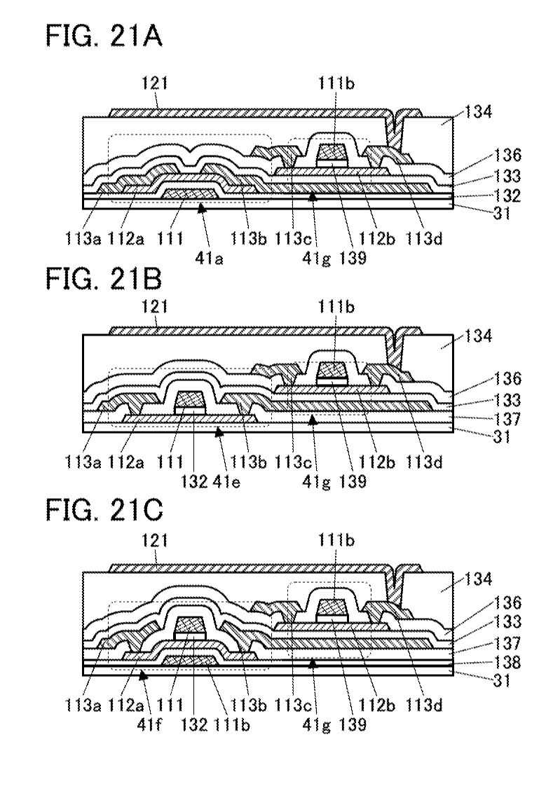

FIG. 21A shows an example in which the transistor 41a is stacked with a transistor 41g.

The transistor 41g is a top-gate transistor whose gate is positioned over the semiconductor layer 112b.

The transistor 41g includes the semiconductor layer 112b over the insulating layer 133, an insulating layer 139 serving as a gate insulating layer over the semiconductor layer 112b, the conductive layer 111b over the insulating layer 139, the insulating layer 136 covering the semiconductor layer 112a and the conductive layer 111b, and the conductive layer 113c and the conductive layer 113d over the insulating layer 136.

The conductive layer 113b and the conductive layer 111b serve as gates of the transistor 41g.

In the example shown in FIG. 21A, a capacitor is formed of each part of the semiconductor layer 112b, the conductive layer 113b, and the insulating layer 133. The capacitor may be used as a storage capacitor. In that case, another capacitor is not necessarily provided.

Although the insulating layer 139 is formed only in the portion overlapping with the conductive layer 111b in the example of FIG. 21A, the insulating layer 132 may cover the end portion of the semiconductor layer 112b as shown in FIG. 20E and the like.

### STRUCTURE EXAMPLE 5

FIG. 21B shows an example in which the transistor 41e is stacked with the transistor 41g. The above description can be referred to for the transistor 41e and the transistor 41g.

Owing to the structure, a display device in which parasitic capacitance is extremely reduced can be achieved.

### STRUCTURE EXAMPLE 6

FIG. 21C shows an example in which the transistor 41f is stacked with the transistor 41g. The above description can be referred to for the transistor 41f and the transistor 41g.

Owing to the structure, a display device in which parasitic capacitance is extremely reduced can be achieved.

The above is the description of the examples of stacked-layer structures of transistors.

### [Components]

The above components will be described below.

### [Substrate]

A material having a flat surface can be used as the substrate included in the display panel. The substrate on the side from which light from the display element is extracted is formed using a material transmitting the light. For example, a material such as glass, quartz, ceramics, sapphire, or an organic resin can be used.

The weight and thickness of the display panel can be reduced by using a thin substrate. A flexible display panel can be obtained by using a substrate that is thin enough to have flexibility.

Since the substrate through which light is not extracted does not need to have a light-transmitting property, a metal substrate or the like can be used, other than the above-mentioned substrates. A metal substrate, which has high thermal conductivity, is preferable because it can easily conduct heat to the whole substrate and accordingly can prevent a local temperature rise in the display panel. To obtain flexibility and bendability, the thickness of a metal substrate is preferably greater than or equal to 10 μm and less than or equal to 200 μm, more preferably greater than or equal to 20 μm and less than or equal to 50 μm.

Although there is no particular limitation on a material of a metal substrate, it is favorable to use, for example, a metal such as aluminum, copper, and nickel, an aluminum alloy, or an alloy such as stainless steel.

It is possible to use a substrate subjected to insulation treatment, e.g., a metal substrate whose surface is oxidized or provided with an insulating film. The insulating film may be formed by, for example, a coating method such as a spin-coating method or a dipping method, an electrodeposition method, an evaporation method, or a sputtering method. An oxide film may be formed on the substrate surface by exposure to or heating in an oxygen atmosphere or by an anodic oxidation method or the like.

Examples of the material that has flexibility and transmits visible light include glass which is thin enough to have flexibility, polyester resins such as polyethylene terephthalate (PET) and polyethylene naphthalate (PEN), a polyacrylonitrile resin, a polyimide resin, a polymethyl methacrylate resin, a polycarbonate (PC) resin, a polyethersulfone (PES) resin, a polyamide resin, a cycloolefin resin, a polystyrene resin, a polyamide imide resin, a polyvinyl chloride resin, and a polytetrafluoroethylene (PTFE) resin. It is particularly preferable to use a material with a low thermal expansion coefficient, for example, a material with a thermal expansion coefficient lower than or equal to 30×10⁻⁶/K, such as a polyamide imide resin, a polyimide resin, or PET. A substrate in which a glass fiber is impregnated with an organic resin or a substrate whose thermal expansion coefficient is reduced by mixing an inorganic filler with an organic resin can also be used. A substrate using such a material is lightweight, and thus a display panel using this substrate can also be lightweight.

In the case where a fibrous body is included in the above material, a high-strength fiber of an organic compound or an inorganic compound is used as the fibrous body. The high-strength fiber is specifically a fiber with a high tensile elastic modulus or a fiber with a high Young's modulus. Typical examples thereof include a polyvinyl alcohol-based fiber, a polyester-based fiber, a polyamide-based fiber, a polyethylene-based fiber, an aramid-based fiber, a polyparaphenylene benzobisoxazole fiber, a glass fiber, and a carbon fiber. As the glass fiber, a glass fiber using E glass, S glass, D glass, Q glass, or the like can be used. These fibers may be used in a state of a woven or nonwoven fabric, and a structure body in which this fibrous body is impregnated with a resin and the resin is cured may be used as the flexible substrate. The structure body including the fibrous body and the resin is preferably used as the flexible substrate, in which case the reliability against bending or breaking due to local pressure can be increased.

Alternatively, glass, metal, or the like that is thin enough to have flexibility can be used as the substrate. Alternatively, a composite material where glass and a resin material are bonded to each other with an adhesive layer may be used.

A hard coat layer (e.g., a silicon nitride layer and an aluminum oxide layer) by which a surface of a display panel is protected from damage, a layer (e.g., an aramid resin layer) that can disperse pressure, or the like may be stacked over the flexible substrate. Furthermore, to suppress a decrease in lifetime of the display element due to moisture and the like, an insulating film with low water permeability may be stacked over the flexible substrate. For example, an inorganic insulating material such as silicon nitride, silicon oxynitride, silicon nitride oxide, aluminum oxide, or aluminum nitride can be used.

The substrate may be formed by stacking a plurality of layers. When a glass layer is used, a barrier property against water and oxygen can be improved and thus a highly reliable display panel can be provided.

### [Transistor]

The transistor includes a conductive layer serving as a gate electrode, a semiconductor layer, a conductive layer serving as a source electrode, a conductive layer serving as a drain electrode, and an insulating layer serving as a gate insulating layer. In the above, a bottom-gate transistor is used.

Note that there is no particular limitation on the structure of the transistor included in the display device of one embodiment of the present invention. For example, a planar transistor, a staggered transistor, or an inverted staggered transistor can be used. A top-gate transistor or a bottom-gate transistor may also be used. Gate electrodes may be provided above and below a channel.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferred that a semiconductor having crystallinity be used, in which case deterioration of the transistor characteristics can be suppressed.

As a semiconductor material used for the transistor, an element of Group 14 (e.g., silicon or germanium), a compound semiconductor, or an oxide semiconductor can be used, for example. Typically, a semiconductor containing silicon, a semiconductor containing gallium arsenide, an oxide semiconductor containing indium, or the like can be used.

In particular, an oxide semiconductor having a wider band gap than silicon is preferably used. A semiconductor material having a wider band gap and a lower carrier density than silicon is preferably used because the off-state leakage current of the transistor can be reduced.

For the semiconductor layer, it is particularly preferable to use an oxide semiconductor including a plurality of crystal parts whose c-axes are aligned substantially perpendicular to a surface on which the semiconductor layer is formed or the top surface of the semiconductor layer and in which a grain boundary is not observed between adjacent crystal parts.

There is no grain boundary in such an oxide semiconductor; therefore, generation of a crack in an oxide semiconductor film which is caused by stress when a display panel is bent is prevented. Therefore, such an oxide semiconductor can be preferably used for a flexible display panel which is used in a bent state, or the like.

Moreover, the use of such an oxide semiconductor with crystallinity for the semiconductor layer makes it possible to provide a highly reliable transistor with a small change in electrical characteristics.

In a transistor with an oxide semiconductor whose band gap is larger than the band gap of silicon, charges stored in a capacitor that is connected in series to the transistor can be held for a long time, owing to the low off-state current of the transistor. When such a transistor is used for a pixel, operation of a driver circuit can be stopped while a gray scale of images displayed on the display region pixel is maintained. As a result, a display device with extremely low power consumption is obtained.

The semiconductor layer preferably includes, for example, a film represented by an

In-M-Zn-based oxide that contains at least indium, zinc, and M (a metal such as aluminum, titanium, gallium, germanium, yttrium, zirconium, lanthanum, cerium, tin, neodymium, or hafnium). In order to reduce variations in electrical characteristics of the transistor including the oxide semiconductor, the oxide semiconductor preferably contains a stabilizer in addition to In, Zn, and M.

Examples of the stabilizer, including metals that can be used as M, are gallium, tin, hafnium, aluminum, and zirconium. As another examples of the stabilizer, lanthanoid such as lanthanum, cerium, praseodymium, neodium, samarium, europium, gadolinium, terbium, dysprosium, holmium, erbium, thulium, ytterbium, or lutetium can be given.

As an oxide semiconductor included in the semiconductor layer, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, an “In—Ga—Zn-based oxide” means an oxide containing In, Ga, and Zn as its main components and there is no limitation on the ratio of In: Ga: Zn. Furthermore, a metal element in addition to In, Ga, and Zn may be contained.

The semiconductor layer and the conductive layer may include the same metal elements contained in the above oxides. The use of the same metal elements for the semiconductor layer and the conductive layer can reduce the manufacturing cost. For example, the use of metal oxide targets with the same metal composition can reduce the manufacturing cost. In addition, the same etching gas or the same etchant can be used in processing the semiconductor layer and the conductive layer. Note that even when the semiconductor layer and the conductive layer include the same metal elements, they have different compositions in some cases. For example, a metal element in a film is released during the manufacturing process of the transistor and the capacitor, which might result in different metal compositions.

The energy gap of the oxide semiconductor included in the semiconductor layer is 2 eV or more, preferably 2.5 eV or more, and more preferably 3 eV or more. The use of such an oxide semiconductor having a wide energy gap leads to a reduction in off-state current of a transistor.

In the case where the oxide semiconductor included in the semiconductor layer is an In—M—Zn oxide, it is preferable that the atomic ratio of metal elements of a sputtering target used for forming a film of the In—M—Zn oxide satisfy In M and Zn M As the atomic ratio of metal elements of such a sputtering target, In: M: Zn=1:1:1, In: M: Zn=1:1:1.2, In: M: Zn=3:1:2, In: M: Zn=4:2:4.1 and the like are preferable. Note that the atomic ratio of metal elements in the formed semiconductor layer varies from the above atomic ratio of metal elements of the sputtering target within a range of ±40% as an error.

An oxide semiconductor film with low carrier density is used as the semiconductor layer. For example, the semiconductor layer is an oxide semiconductor film whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³. Such an oxide semiconductor is referred to as a highly purified intrinsic or substantially highly purified intrinsic oxide semiconductor. The oxide semiconductor has a low impurity concentration and a low density of defect states and can thus be referred to as an oxide semiconductor having stable characteristics.

Note that, without limitation to those described above, a material with an appropriate composition may be used depending on required semiconductor characteristics and electrical characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

When silicon or carbon that is one of elements belonging to Group 14 is contained in the oxide semiconductor contained in the semiconductor layer, oxygen vacancies are increased in the semiconductor layer, and the semiconductor layer becomes n-type. Thus, the concentration of silicon or carbon (measured by secondary ion mass spectrometry) in the semiconductor layer is lower than or equal to 2×10¹⁸ atoms/cm³, preferably lower than or equal to 2×10¹⁷ atoms/cm³.

Alkali metal and alkaline earth metal might generate carriers when bonded to an oxide semiconductor, in which case the off-state current of the transistor might be increased. Therefore, the concentration of alkali metal or alkaline earth metal of the semiconductor layer, which is measured by secondary ion mass spectrometry, is lower than or equal to 1×10¹⁸ atoms/cm³, preferably lower than or equal to 2×10¹⁶ atoms/cm³.

When nitrogen is contained in the oxide semiconductor contained in the semiconductor layer, electrons serving as carriers are generated and the carrier density increases, so that the semiconductor layer easily becomes n-type. Thus, a transistor including an oxide semiconductor which contains nitrogen is likely to be normally on. Hence, the concentration of nitrogen which is measured by secondary ion mass spectrometry is preferably set to lower than or equal to 5×10¹⁸ atoms/cm³.

The semiconductor layer may have a non-single-crystal structure, for example. The non-single-crystal structure includes CAAC-OS (c-axis aligned crystalline oxide semiconductor, or c-axis aligned a-b-plane-anchored crystalline oxide semiconductor), a polycrystalline structure, a microcrystalline structure, or an amorphous structure, for example. Among the non-single-crystal structures, an amorphous structure has the highest density of defect states, whereas CAAC-OS has the lowest density of defect states.

An oxide semiconductor film having an amorphous structure has disordered atomic arrangement and no crystalline component, for example. Alternatively, an oxide film having an amorphous structure has, for example, an absolutely amorphous structure and no crystal part.

Note that the semiconductor layer may be a mixed film including two or more of the following: a region having an amorphous structure, a region having a microcrystalline structure, a region having a polycrystalline structure, a region of CAAC-OS, and a region having a single-crystal structure. The mixed film has, for example, a single-layer structure or a stacked-layer structure including two or more of the above-described regions in some cases.

### [Composition of CAC-OS]

Described below is the composition of a cloud-aligned composite oxide semiconductor (CAC-OS) applicable to a transistor disclosed in one embodiment of the present invention.

The CAC-OS has, for example, a composition in which elements included in an oxide semiconductor are unevenly distributed. Materials including unevenly distributed elements each have a size of greater than or equal to 0.5 nm and less than or equal to 10 nm, preferably greater than or equal to 1 nm and less than or equal to 2 nm, or a similar size. Note that in the following description of an oxide semiconductor, a state in which one or more metal elements are unevenly distributed and regions including the metal element(s) are mixed is referred to as a mosaic pattern or a patch-like pattern. The region has a size of greater than or equal to 0.5 nm and less than or equal to 10 nm, preferably greater than or equal to 1 nm and less than or equal to 2 nm, or a similar size.

Note that an oxide semiconductor preferably contains at least indium. In particular, indium and zinc are preferably contained. In addition, one or more of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, of the CAC-OS, an In—Ga—Zn oxide with the CAC composition (such an In—Ga—Zn oxide may be particularly referred to as CAC-IGZO) has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and gallium oxide (GaO_{X3}, where X3 is a real number greater than 0) or gallium zinc oxide (Ga_{X4}Zn_{Y4}O_{Z4}, where X4, Y4, and Z4 are real numbers greater than 0), and a mosaic pattern is formed. Then, InO_{X1} or In_{X2}Zn_{Y2}O_{Z2} forming the mosaic pattern is evenly distributed in the film.

This composition is also referred to as a cloud-like composition.

That is, the CAC-OS is a composite oxide semiconductor with a composition in which a region including GaO_{X3} as a main component and a region including In_{X2}Zn_{Y2}O_{Z2} or InO_{X1} as a main component are mixed. Note that in this specification, for example, when the atomic ratio of In to an element M in a first region is greater than the atomic ratio of In to an element M in a second region, the first region has higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In(1+x0)Ga(1−x0)O₃(ZnO)ₘ₀ (−1≦x0≦1; m0 is a given number).

The above crystalline compounds have a single crystal structure, a polycrystalline structure, or a CAAC structure. Note that the CAAC structure is a crystal structure in which a plurality of IGZO nanocrystals have c-axis alignment and are connected in the a-b plane direction without alignment.

On the other hand, the CAC-OS relates to the material composition of an oxide semiconductor. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different atomic ratios is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases.

In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected metal element(s) as a main component(s) are observed in part of the CAC-OS and nanoparticle regions including In as a main component are observed in part thereof, and these nanoparticle regions are randomly dispersed to form a mosaic pattern in the CAC-OS.

The CAC-OS can be formed by a sputtering method under conditions where a substrate is not heated, for example. In the case of forming the CAC-OS by a sputtering method, one or more selected from an inert gas (typically, argon), an oxygen gas, and a nitrogen gas may be used as a deposition gas. The ratio of the flow rate of an oxygen gas to the total flow rate of the deposition gas at the time of deposition is preferably as low as possible, and for example, the flow ratio of an oxygen gas is preferably higher than or equal to 0% and lower than 30%, further preferably higher than or equal to 0% and lower than or equal to 10%.

The CAC-OS is characterized in that no clear peak is observed in measurement using θ/2θ scan by an out-of-plane method, which is an X-ray diffraction (XRD) measurement method. That is, X-ray diffraction shows no alignment in the a-b plane direction and the c-axis direction in a measured region.

In an electron diffraction pattern of the CAC-OS which is obtained by irradiation with an electron beam with a probe diameter of 1 nm (also referred to as a nanometer-sized electron beam), a ring-like region with high luminance and a plurality of bright spots in the ring-like region are observed. Therefore, the electron diffraction pattern indicates that the crystal structure of the CAC-OS includes a nanocrystal (nc) structure with no alignment in plan-view and cross-sectional directions.

For example, an energy dispersive X-ray spectroscopy (EDX) mapping image confirms that an In—Ga—Zn oxide with the CAC composition has a structure in which a region including GaO_{X3} as a main component and a region including In_{X2}Zn_{Y2}O_{Z2} or InO_{X1} are unevenly distributed and mixed.

The CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn_{Y2}O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is exhibited. Accordingly, when regions including In_{X2}Zn_{Y2}O_{Z2} or InO_{X1} as a main component are distributed in an oxide semiconductor like a cloud, high field-effect mobility (μ) can be achieved.

In contrast, the insulating property of a region including GaO_{X3} or the like as a main component is higher than that of a region including In_{X2}Zn_{Y2}O_{Z2} or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used for a semiconductor element, the insulating property derived from GaO_{X3} or the like and the conductivity derived from In_{X2}Zn_{Y2}O_{Z2} or InO_{X1} complement each other, whereby high on-state current (Iₒₙ) and high field-effect mobility (μ) can be achieved.

A semiconductor element including a CAC-OS has high reliability. Thus, the CAC-OS is suitably used in a variety of semiconductor devices typified by a display.

Alternatively, silicon is preferably used as a semiconductor in which a channel of a transistor is formed. Although amorphous silicon may be used as silicon, silicon having crystallinity is particularly preferable. For example, microcrystalline silicon, polycrystalline silicon, single-crystal silicon, or the like is preferably used. In particular, polycrystalline silicon can be formed at a lower temperature than single-crystal silicon and has higher field effect mobility and higher reliability than amorphous silicon. When such a polycrystalline semiconductor is used for a pixel, the aperture ratio of the pixel can be improved. Even in the case where the display portion with extremely high definition is provided, a gate driver circuit and a source driver circuit can be formed over a substrate over which the pixels are formed, and the number of components of an electronic device can be reduced.

The bottom-gate transistor described in this embodiment is preferable because the number of manufacturing steps can be reduced. When amorphous silicon, which can be formed at a lower temperature than polycrystalline silicon, is used for the semiconductor layer, materials with low heat resistance can be used for a wiring, an electrode, or a substrate below the semiconductor layer, resulting in wider choice of materials. For example, an extremely large glass substrate can be favorably used. Meanwhile, the top-gate transistor is preferable because an impurity region is easily formed in a self-aligned manner and variation in characteristics can be reduced. In that case, the use of polycrystalline silicon, single-crystal silicon, or the like is particularly preferable.

### [Conductive Layer]

As materials for the gates, the source, and the drain of a transistor, and the conductive layers serving as the wirings and electrodes included in the display device, any of metals such as aluminum, titanium, chromium, nickel, copper, yttrium, zirconium, molybdenum, silver, tantalum, and tungsten, or an alloy containing any of these metals as its main component can be used. A single-layer structure or a layered structure including a film containing any of these materials can be used. For example, the following structures can be given: a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, and a three-layer structure in which a molybdenum film or a molybdenum nitride film, an aluminum film or a copper film, and a molybdenum film or a molybdenum nitride film are stacked in this order. Note that an oxide such as indium oxide, tin oxide, or zinc oxide may be used. Copper containing manganese is preferably used because controllability of a shape by etching is increased.

As a light-transmitting conductive material, a conductive oxide such as indium oxide, indium tin oxide, indium zinc oxide, zinc oxide, or zinc oxide to which gallium is added, or graphene can be used. Alternatively, a metal material such as gold, silver, platinum, magnesium, nickel, tungsten, chromium, molybdenum, iron, cobalt, copper, palladium, or titanium or an alloy material containing any of these metal materials can be used. Alternatively, a nitride of the metal material (e.g., titanium nitride) or the like may be used. In the case of using the metal material or the alloy material (or the nitride thereof), the thickness is set small enough to allow light transmission. Alternatively, a layered film of any of the above materials can be used as the conductive layer. For example, a layered film of indium tin oxide and an alloy of silver and magnesium is preferably used because the conductivity can be increased. They can also be used for conductive layers such as a variety of wirings and electrodes included in a display device, and conductive layers (e.g., conductive layers serving as a pixel electrode or a common electrode) included in a display element.

### [Insulating Layer]

Examples of an insulating material that can be used for the insulating layers include a resin such as acrylic or epoxy resin, a resin having a siloxane bond, and an inorganic insulating material such as silicon oxide, silicon oxynitride, silicon nitride oxide, silicon nitride, or aluminum oxide.

The light-emitting element is preferably provided between a pair of insulating films with low water permeability, in which case entry of impurities such as water into the light-emitting element can be inhibited. Thus, a decrease in device reliability can be suppressed.

As an insulating film with low water permeability, a film containing nitrogen and silicon, such as a silicon nitride film or a silicon nitride oxide film, a film containing nitrogen and aluminum, such as an aluminum nitride film, or the like can be used. Alternatively, a silicon oxide film, a silicon oxynitride film, an aluminum oxide film, or the like may be used.

For example, the amount of water vapor transmission of the insulating film with low water permeability is lower than or equal to 1×10⁻⁵ [g/(m²·day)], preferably lower than or equal to 1×10⁻⁶ [g/(m²·day)], more preferably lower than or equal to 1×10⁻⁷ [g/(m²·day)], still more preferably lower than or equal to 1×10⁻⁸ [g/(m²·day)].

### [Light-Emitting Element]

As the light-emitting element, a self-luminous element can be used, and an element whose luminance is controlled by current or voltage is included in the category of the light-emitting element. For example, an LED, an organic EL element, an inorganic EL element, or the like can be used.

The light-emitting element can have a top emission structure, a bottom emission structure, a dual emission structure, and the like. A conductive film that transmits visible light is used as the electrode through which light is extracted. A conductive film that reflects visible light is preferably used as the electrode through which light is not extracted.

The EL layer includes at least a light-emitting layer. In addition to the light-emitting layer, the EL layer may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

For the EL layer, either a low-molecular compound or a high-molecular compound can be used, and an inorganic compound may also be used. Each of the layers included in the EL layer can be formed by any of the following methods: an evaporation method (including a vacuum evaporation method), a transfer method, a printing method, an inkjet method, a coating method, and the like.

When a voltage higher than the threshold voltage of the light-emitting element is applied between a cathode and an anode, holes are injected to the EL layer from the anode side and electrons are injected to the EL layer from the cathode side. The injected electrons and holes are recombined in the EL layer and a light-emitting substance contained in the EL layer emits light.

In the case where a light-emitting element emitting white light is used as the light-emitting element, the EL layer preferably contains two or more kinds of light-emitting substances. For example, the two or more kinds of light-emitting substances are selected so as to emit light of complementary colors to obtain white light emission. Specifically, it is preferable to contain two or more selected from light-emitting substances that emit light of red (R), green (G), blue (B), yellow (Y), orange (0), and the like and light-emitting substances that emit light containing two or more of spectral components of R, G, and B. The light-emitting element preferably emits light with a spectrum having two or more peaks in the wavelength range of a visible light region (e.g., 350 nm to 750 nm). An emission spectrum of a material that emits light having a peak in a yellow wavelength range preferably includes spectral components also in green and red wavelength ranges.

A light-emitting layer containing a light-emitting material that emits light of one color and a light-emitting layer containing a light-emitting material that emits light of another color are preferably stacked in the EL layer. For example, the plurality of light-emitting layers in the EL layer may be stacked in contact with each other or may be stacked with a region not including any light-emitting material therebetween. For example, between a fluorescent layer and a phosphorescent layer, a region containing the same material as one in the fluorescent layer or the phosphorescent layer (for example, a host material or an assist material) and no light-emitting material may be provided. This facilitates the manufacture of the light-emitting element and reduces the drive voltage.

The light-emitting element may be a single element including one EL layer or a tandem element in which a plurality of EL layers are stacked with a charge generation layer therebetween.

The conductive film that transmits visible light can be formed using, for example, indium oxide, indium tin oxide, indium zinc oxide, zinc oxide, or zinc oxide to which gallium is added. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be formed thin so as to have a light-transmitting property. Alternatively, a stack of any of the above materials can be used for the conductive layers. For example, a stack of indium tin oxide and an alloy of silver and magnesium is preferably used, in which case conductivity can be increased. Still alternatively, graphene or the like may be used.

For the conductive film that reflects visible light, for example, a metal material such as aluminum, gold, platinum, silver, nickel, tungsten, chromium, molybdenum, iron, cobalt, copper, or palladium or an alloy containing any of these metal materials can be used. Furthermore, lanthanum, neodymium, germanium, or the like may be added to the metal material or the alloy. Alternatively, an alloy containing aluminum (an aluminum alloy) such as an alloy of aluminum and titanium, an alloy of aluminum and nickel, or an alloy of aluminum and neodymium may be used. Alternatively, an alloy containing silver such as an alloy of silver and copper, an alloy of silver and palladium, or an alloy of silver and magnesium may be used. An alloy containing silver and copper is preferable because of its high heat resistance. Furthermore, when a metal film or a metal oxide film is stacked in contact with an aluminum film or an aluminum alloy film, oxidation can be suppressed. Examples of a material for the metal film or the metal oxide film include titanium and titanium oxide. Alternatively, the above conductive film that transmits visible light and a film containing a metal material may be stacked. For example, a stack of silver and indium tin oxide, a stack of an alloy of silver and magnesium and indium tin oxide, or the like can be used.

Each of the electrodes can be formed by an evaporation method or a sputtering method. Alternatively, a discharging method such as an inkjet method, a printing method such as a screen printing method, or a plating method may be used.

Note that the aforementioned light-emitting layer and layers containing a substance with a high hole-injection property, a substance with a high hole-transport property, a substance with a high electron-transport property, a substance with a high electron-injection property, a substance with a bipolar property, and the like may include an inorganic compound such as a quantum dot or a high molecular compound (e.g., an oligomer, a dendrimer, and a polymer). For example, when used for the light-emitting layer, the quantum dot can function as a light-emitting material.

The quantum dot may be a colloidal quantum dot, an alloyed quantum dot, a core-shell quantum dot, a core quantum dot, or the like. A quantum dot containing elements belonging to Groups 12 and 16, elements belonging to Groups 13 and 15, or elements belonging to Groups 14 and 16 may be used. Alternatively, a quantum dot containing an element such as cadmium, selenium, zinc, sulfur, phosphorus, indium, tellurium, lead, gallium, arsenic, or aluminum may be used.

### [Adhesive Layer]

As the adhesive layer, any of a variety of curable adhesives, e.g., a photo-curable adhesive such as an ultraviolet curable adhesive, a reactive curable adhesive, a thermosetting curable adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. Alternatively, a two-component-mixture-type resin may be used. Still alternatively, an adhesive sheet or the like may be used.

Furthermore, the resin may include a drying agent. For example, a substance that adsorbs moisture by chemical adsorption, such as oxide of an alkaline earth metal (e.g., calcium oxide or barium oxide), can be used. Alternatively, a substance that adsorbs moisture by physical adsorption, such as zeolite or silica gel, may be used. The drying agent is preferably included because it can inhibit entry of impurities such as moisture into an element, leading to an improvement in the reliability of the display panel.

In addition, a filler with a high refractive index or a light-scattering member may be mixed into the resin, in which case light extraction efficiency can be improved. For example, titanium oxide, barium oxide, zeolite, or zirconium can be used.

### [Connection Layer]

As a connection layer, an anisotropic conductive film (ACF), an anisotropic conductive paste (ACP), or the like can be used.

### [Coloring Layer]

Examples of materials that can be used for the coloring layer include a metal material, a resin material, and a resin material containing a pigment or dye.

### [Light-Blocking Layer]

Examples of a material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked-layer structure of a film containing a material of a coloring layer which transmits light of a certain color and a film containing a material of a coloring layer which transmits light of another color can be employed. It is preferred that the coloring layer and the light-blocking layer be formed using the same material because the same manufacturing apparatus can be used and the process can be simplified.

The above is the description of each of the components.

### [Example Of Manufacturing Method]

Here, a manufacturing method example of a display panel using a flexible substrate is described.

Here, layers each including a display element, a circuit, a wiring, an electrode, optical members such as a coloring layer and a light-blocking layer, an insulating layer, and the like, are collectively referred to as an element layer. The element layer includes, for example, a display element, and may additionally include a wiring electrically connected to the display element or an element such as a transistor used in a pixel or a circuit.

In addition, here, a flexible member which supports the element layer at a stage at which the display element is completed (the manufacturing process is finished) is referred to as a substrate. For example, a substrate includes an extremely thin film with a thickness greater than or equal to 10 nm and less than or equal to 300 μm and the like.

As a method for forming an element layer over a flexible substrate provided with an insulating surface, typically, there are two methods shown below. One of them is to directly form an element layer over the substrate. The other method is to form an element layer over a support substrate that is different from the substrate and then to separate the element layer from the support substrate to be transferred to the substrate. Although not described in detail here, in addition to the above two methods, there is a method in which the element layer is formed over a substrate which does not have flexibility and the substrate is thinned by polishing or the like to have flexibility.

In the case where a material of the substrate can withstand heating temperature in a process for forming the element layer, it is preferable that the element layer be formed directly over the substrate, in which case a manufacturing process can be simplified. At this time, the element layer is preferably formed in a state where the substrate is fixed to a support substrate, in which case transfer thereof in an apparatus and between apparatuses can be easy.

In the case of employing the method in which the element layer is formed over the support substrate and then transferred to the substrate, first, a separation layer and an insulating layer are stacked over the support substrate, and then the element layer is formed over the insulating layer. Next, the element layer is separated from the support substrate and then transferred to the substrate. At this time, selected is a material with which separation at an interface between the support substrate and the separation layer, at an interface between the separation layer and the insulating layer, or in the separation layer occurs. With the method, it is preferable that a material having high heat resistance be used for the support substrate or the separation layer, in which case the upper limit of the temperature applied when the element layer is formed can be increased, and an element layer including a higher reliable element can be formed.

For example, it is preferable that a stack of a layer containing a high-melting-point metal material, such as tungsten, and a layer containing an oxide of the metal material be used as the separation layer, and a stack of a plurality of layers, such as a silicon oxide layer, a silicon nitride layer, a silicon oxynitride layer, and a silicon nitride oxide layer be used as the insulating layer over the separation layer. Note that in this specification, oxynitride contains more oxygen than nitrogen, and nitride oxide contains more nitrogen than oxygen.

As the method for separating the support substrate from the element layer, applying mechanical force, etching the separation layer, and making a liquid permeate the separation interface are given as examples. Alternatively, separation may be performed by heating or cooling the support substrate by utilizing a difference in thermal expansion coefficient of two layers which form the separation interface.

The separation layer is not necessarily provided in the case where the separation can be performed at an interface between the support substrate and the insulating layer.

For example, glass and an organic resin such as polyimide can be used as the support substrate and the insulating layer, respectively. In that case, a separation trigger may be formed by, for example, locally heating part of the organic resin with laser light or the like, or by physically cutting part of or making a hole through the organic resin with a sharp tool, so that separation may be performed at an interface between the glass and the organic resin.

Alternatively, a heat generation layer may be provided between the support substrate and the insulating layer formed of an organic resin, and separation may be performed at an interface between the heat generation layer and the insulating layer by heating the heat generation layer. As the heat generation layer, any of a variety of materials such as a material which generates heat by feeding current, a material which generates heat by absorbing light, and a material which generates heat by applying a magnetic field can be used. For example, for the heat generation layer, a material selected from a semiconductor, a metal, and an insulator can be used.

In the above-described methods, the insulating layer formed of an organic resin can be used as a substrate after the separation.

The above is the description of the manufacturing method of the display panel with a flexible substrate.

At least part of this embodiment can be implemented in combination with any of the other embodiments described in this specification as appropriate.

### Embodiment 2

In this embodiment, a structure example of a display device of one embodiment of the present invention will be described. In the below-described display device, two display panels are stacked.

### [Structure Example]

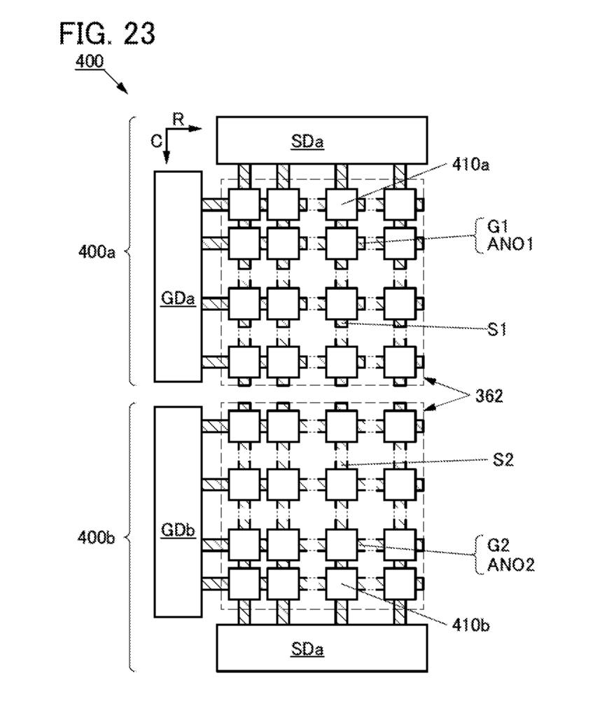

FIG. 23 is a block diagram illustrating an example of the structure of a display device 400. The display device 400 includes a display panel 400a and a display panel 400b. Although the display panel 400a and the display panel 400b are provided side by side in FIG. 23, they are stacked actually.

The display panel 400a includes a plurality of pixels 410a that are arranged in a matrix in a display portion 362. The display panel 400a also includes a circuit GDa and a circuit SDa.

The display panel 400b includes a plurality of pixels 410b that are arranged in a matrix in a display portion 362. The display panel 400b also includes a circuit GDb and a circuit SDb.

The display panel 400a includes a plurality of wirings G1 and a plurality of wirings ANO1 electrically connecting the circuit GDa and the plurality of pixels 410a arranged in a direction R. In addition, the display panel 400a includes a plurality of wirings 51 electrically connecting the circuit SDa and a plurality of pixels 410a arranged in a direction C.

The display panel 400a includes a plurality of wirings G2 and a plurality of wirings ANO2 electrically connecting the circuit GDb and the plurality of pixels 410b arranged in the direction R. In addition, the display panel 400b includes a plurality of wirings S2 electrically connecting the circuit SDb and a plurality of pixels 410b arranged in the direction C.

The pixel 410a and the pixel 410b each include a light-emitting element. The light-emitting element of the pixel 410a and the light-emitting element of the pixel 410b have a region where they do not overlap with each other.

### [Circuit Configuration Example]

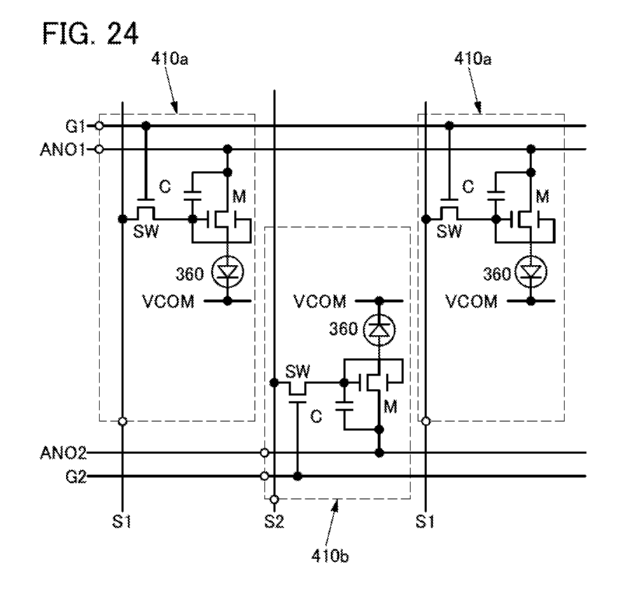

FIG. 24 is a circuit diagram showing a structure example of the pixel 410a and the pixel 410b included in the display portion 362. FIG. 24 shows three adjacent pixels.

The pixel 410a and the pixel 410b are similar in configuration except the connecting wirings. Thus, their common parts may be described for either one of them.

Each of the pixel 410a and the pixel 410b includes a switch SW, a transistor M, a capacitor C, a light-emitting element 360, and the like. The pixel 410a is electrically connected to a wiring G1, a wiring ANO1, and a wiring S1. The pixel 410b is electrically connected to a wiring G2, a wiring ANO2, and a wiring S2.

In the pixel 410a, a gate of the switch SW is connected to the wiring G1. One of a source and a drain of the switch SW is connected to the wiring S1, and the other of the source and the drain is connected to one electrode of the capacitor C and a gate of the transistor M. The other electrode of the capacitor C is connected to one of a source and a drain of the transistor M and the wiring ANO1. The other of the source and the drain of the transistor M is connected to one electrode of the light-emitting element 360. The other electrode of the light-emitting element 360 is connected to the wiring VCOM.

FIG. 24 illustrates an example in which the transistor M includes two gates between which a semiconductor is provided and which are connected to each other. This structure can increase the amount of current flowing through the transistor M.

The wiring G1 and the wiring G2 can be supplied with a signal for changing the on/off state of the switch SW. The wiring VCOM, the wiring ANO1, and the wiring ANO2 can be supplied with potentials having a difference large enough to make the light-emitting element 360 emit light. The wiring S1 and the wiring S2 can be supplied with a signal for changing the conduction state of the transistor M.

At least part of this embodiment can be implemented in combination with any of the other embodiments described in this specification as appropriate.

### Embodiment 3

In this embodiment, a display module that can be fabricated using one embodiment of the present invention will be described.

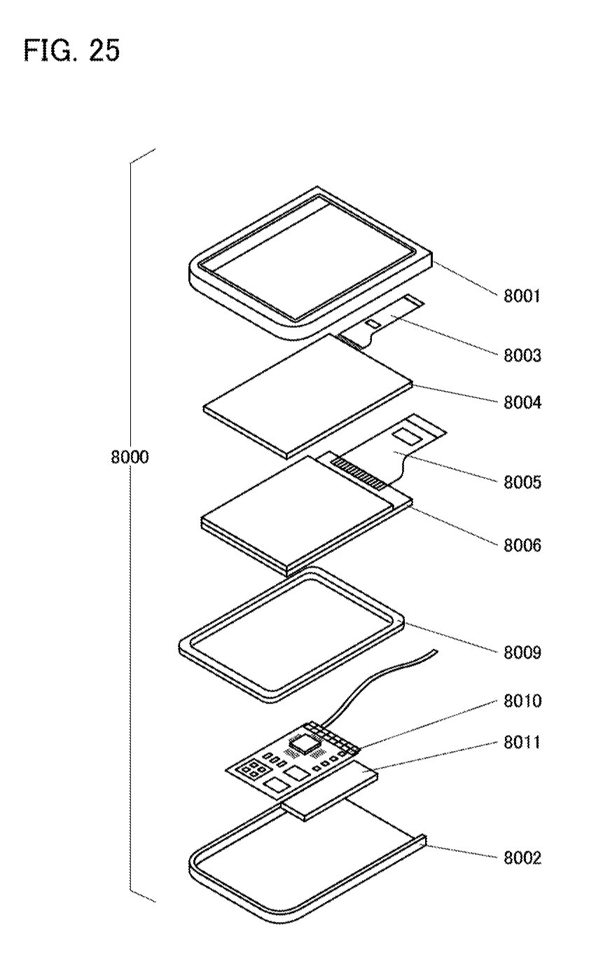

In a display module 8000 in FIG. 25, a touch panel 8004 connected to an FPC 8003, a display panel 8006 connected to an FPC 8005, a frame 8009, a printed circuit board 8010, and a battery 8011 are provided between an upper cover 8001 and a lower cover 8002.

The display device fabricated using one embodiment of the present invention can be used for, for example, the display panel 8006.

The shapes and sizes of the upper cover 8001 and the lower cover 8002 can be changed as appropriate in accordance with the sizes of the touch panel 8004 and the display panel 8006.

The touch panel 8004 can be a resistive touch panel or a capacitive touch panel and may be formed to overlap with the display panel 8006. Instead of providing the touch panel 8004, the display panel 8006 can have a touch panel function.

The frame 8009 protects the display panel 8006 and functions as an electromagnetic shield for blocking electromagnetic waves generated by the operation of the printed circuit board 8010. The frame 8009 may also function as a radiator plate.

The printed circuit board 8010 has a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 may be additionally provided with a member such as a polarizing plate, a retardation plate, or a prism sheet.

At least part of this embodiment can be implemented in appropriate combination with any of the other embodiments described in this specification.

### Embodiment 4

In this embodiment, electronic devices to which the display device of one embodiment of the present invention can be applied will be described.

The display device of one embodiment of the present invention can be used for a display portion of an electronic device. As a result, the electronic device can have high display quality, extremely high resolution, or high reliability.

Examples of electronic devices include a television set, a desktop or laptop personal computer, a monitor of a computer or the like, a digital camera, a digital video camera, a digital photo frame, a mobile phone, a portable game machine, a portable information terminal, an audio reproducing device, and a large game machine such as a pachinko machine.

The electronic device or the lighting device of one embodiment of the present invention can be incorporated along a curved inside/outside wall surface of a house or a building or a curved interior/exterior surface of a car.

The electronic device of one embodiment of the present invention may include a secondary battery. It is preferable that the secondary battery be capable of being charged by non-contact power transmission.

Examples of the secondary battery include a lithium ion secondary battery such as a lithium polymer battery using a gel electrolyte (lithium ion polymer battery), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display an image, data, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, chemical substance, sound, time, hardness, electric field, electric current, voltage, electric power, radiation, flow rate, humidity, gradient, oscillation, odor, or infrared rays).

The electronic device of one embodiment of the present invention can have a variety of functions such as a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

Furthermore, the electronic device including a plurality of display portions can have a function of displaying image information mainly on one display portion while displaying text information mainly on another display portion, a function of displaying a three-dimensional image by displaying images where parallax is considered on a plurality of display portions, or the like. Furthermore, the electronic device including an image receiving portion can have a function of photographing a still image or a moving image, a function of automatically or manually correcting a photographed image, a function of storing a photographed image in a recording medium (an external recording medium or a recording medium incorporated in the electronic device), a function of displaying a photographed image on a display portion, or the like. Note that the functions of the electronic devices of embodiments of the present invention are not limited thereto, and the electronic devices can have a variety of functions.

The display device of one embodiment of the present invention can display images with extremely high resolution. For this reason, the display device can be used particularly for portable electronic devices, wearable electronic devices (wearable devices), e-book readers, and the like. In addition, the display device can be suitably used for virtual reality (VR) devices, augmented reality (AR) devices, and the like.

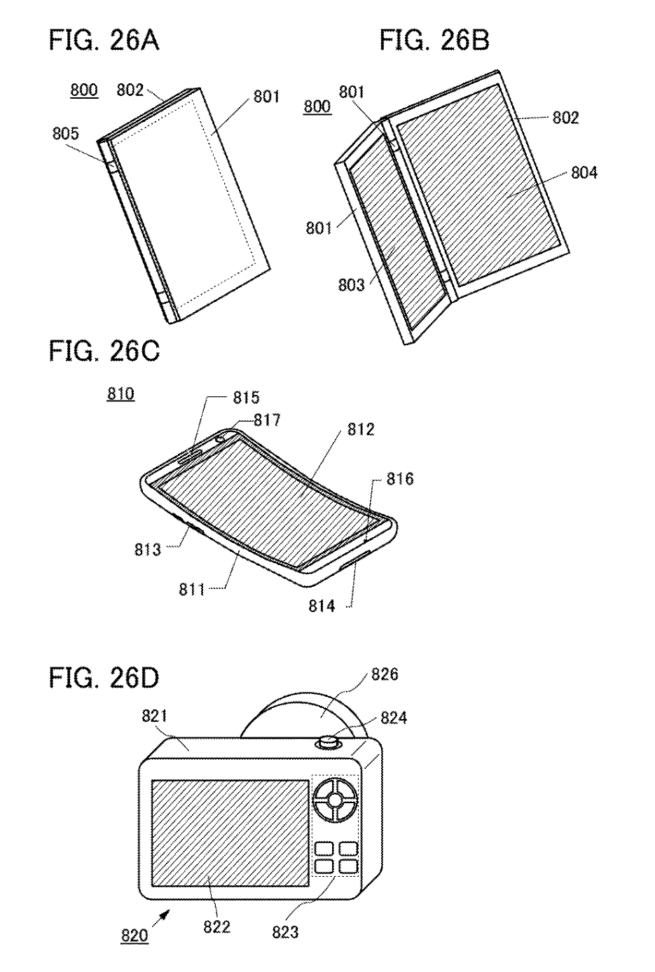

FIGS. 26A and 26B illustrate an example of a portable information terminal 800. The portable information terminal 800 includes a housing 801, a housing 802, a display portion 803, a display portion 804, and a hinge 805, for example.

At least one of the display portion 803 and the display portion 804 includes the display device of one embodiment of the present invention.

The housing 801 and the housing 802 are connected with the hinge portion 805. The portable information terminal 800 folded as in FIG. 26A can be changed into the state illustrated in FIG. 26B, in which the housing 801 and the housing 802 are opened.

For example, the portable information terminal 800 can also be used as an e-book reader, in which the display portion 803 and the display portion 804 each can display text data. In addition, the display portion 803 and the display portion 804 each can display a still image or a moving image.

In this manner, the portable information terminal 800 has high versatility because it can be folded when carried.

Note that the housing 801 and the housing 802 may include a power switch, an operation button, an external connection port, a speaker, a microphone, and/or the like.

FIG. 26C illustrates an example of a portable information terminal. A portable information terminal 810 illustrated in FIG. 26C includes a housing 811, a display portion 812, operation buttons 813, an external connection port 814, a speaker 815, a microphone 816, a camera 817, and the like.

The display portion 812 is provided with the display device of one embodiment of the present invention.

The portable information terminal 810 includes a touch sensor in the display portion 812. Operations such as making a call and inputting a letter can be performed by touch on the display portion 812 with a finger, a stylus, or the like.

With the operation buttons 813, power on/off can be switched and types of images displayed on the display portion 812 can be switched. For example, images can be switched from a mail creation screen to a main menu screen.

When a detection device such as a gyroscope sensor or an acceleration sensor is provided inside the portable information terminal 810, the direction of display on the screen of the display portion 812 can be automatically changed by determining the orientation of the portable information terminal 810 (whether the portable information terminal 810 is placed horizontally or vertically). The direction of display on the screen can also be changed by touch on the display portion 812, operation with the operation buttons 813, sound input using the microphone 816, or the like.

The portable information terminal 810 has one or more of a telephone function, a notebook function, an information browsing function, and the like. Specifically, the portable information terminal 810 can be used as a smartphone. The portable information terminal 810 is capable of executing a variety of applications such as mobile phone calls, e-mailing, viewing and editing texts, music reproduction, video replay, Internet communication, and games.

FIG. 26D illustrates an example of a camera. A camera 820 includes a housing 821, a display portion 822, operation buttons 823, a shutter button 824, and the like. The camera 820 is provided with an attachable lens 826.

The display portion 822 is provided with the display device of one embodiment of the present invention.

Although the lens 826 of the camera 820 here is detachable from the housing 821 for replacement, the lens 826 may be integrated with the housing 821.

Still images or moving images can be taken with the camera 820 by pushing the shutter button 824. In addition, images can be taken by a touch on the display portion 822 that serves as a touch panel.

Note that a stroboscope, a viewfinder, or the like can be additionally provided in the camera 820. Alternatively, these can be incorporated in the housing 821.

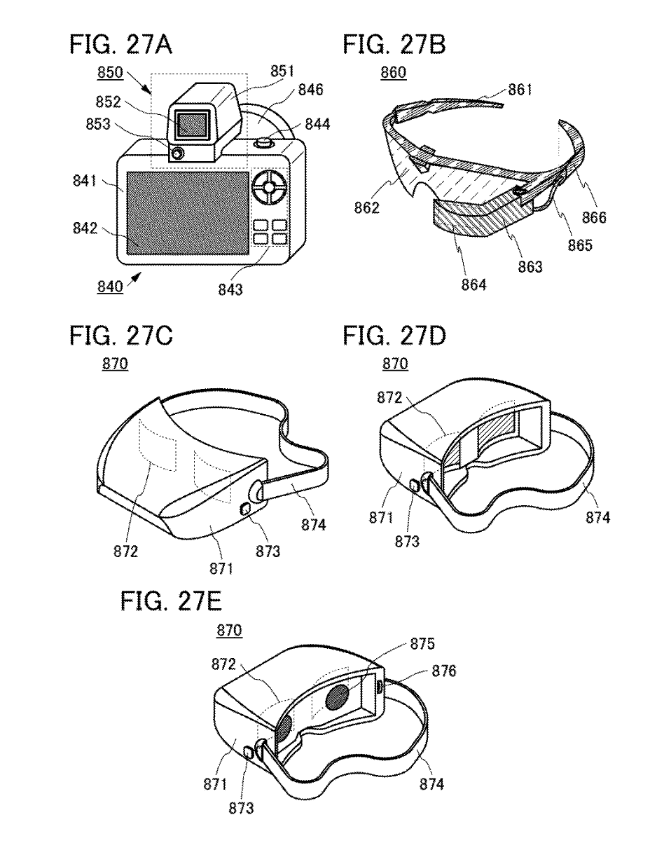

FIG. 27A is an external view of a camera 840 to which a finder 850 is attached.

The camera 840 includes a housing 841, a display portion 842, an operation button 843, a shutter button 844, and the like. Furthermore, an attachable lens 846 is attached to the camera 840.

Although the lens 846 of the camera 840 here is detachable from the housing 841 for replacement, the lens 846 may be built into a housing.

When the shutter button 844 is pressed, the camera 840 can take images. In addition, the display portion 842 has a function of a touch panel, and images can be taken when the display portion 842 is touched.

The housing 841 of the camera 840 has a mount including an electrode, and the finder 850, a stroboscope, and the like can be connected.

The finder 850 includes a housing 851, a display portion 852, a button 853, and the like.

The housing 851 includes a mount for engagement with the mount of the camera 840 so that the finder 850 can be connected to the camera 840. The mount includes an electrode, and a moving image or the like received from the camera 840 through the electrode can be displayed on the display portion 852.

The button 853 serves as a power button. The display portion 852 can be turned on and off using the button 853.

A display device of one embodiment of the present invention can be used for the display portion 842 of the camera 840 and the display portion 852 of the finder 850.

Although the camera 840 and the finder 850 are separate and detachable electronic devices in FIG. 27A, a finder including the display device of one embodiment of the present invention may be built into the housing 841 of the camera 840.

FIG. 27B is an external view of a head-mounted display 860.

The head-mounted display 860 includes a mounting portion 861, a lens 862, a main body 863, a display portion 864, a cable 865, and the like. In addition, a battery 866 is built into the mounting portion 861.

Power is supplied from the battery 866 to the main body 863 through the cable 865.

The main body 863 includes a wireless receiver or the like to receive video data such as image data and display it on the display portion 864. The movement of the user's eyeball or eyelid is captured by a camera in the main body 863 and then the coordinates of the eyepoint are calculated using the captured data to utilize the user's eye as an input portion.

A plurality of electrodes may be provided in a portion of the mounting portion 861 a user touches. The main body 863 may have a function of sensing a current flowing through the electrodes with the movement of the user's eyeball to determine the location of the eyepoint. The main body 863 may have a function of sensing a current flowing through the electrodes to monitor the user's pulse. The mounting portion 861 may include sensors such as a temperature sensor, a pressure sensor, or an acceleration sensor so that the user's biological information can be displayed on the display portion 864. The main body 863 may sense the movement of the user's head or the like to move an image displayed on the display portion 864 in synchronization with the movement of the user's head, or the like.

The display device of one embodiment of the present invention can be used for the display portion 864.

FIGS. 27C and 27D are external views of a head-mounted display 870.

The head-mounted display 870 includes a housing 871, two display portions 872, an operation button 873, and a fixing band 874.

The head-mounted display 870 has the functions of the above-described head-mounted display 860 and includes two display portions.

Since the head-mounted display 870 includes the two display portions 872, the user's eyes can see their respective display portions. Thus, a high-definition image can be displayed even when a three-dimensional display using parallax, or the like, is performed. In addition, the display portion 872 is curved around an arc with the user's eye as an approximate center.

Owing to this, the distance between the user's eye and the display surface of the display portion is uniform; thus, the user can see a more natural image. Even when the luminance or chromaticity of light emitted from the display portion varies depending on the user' viewing angle, the influence of the variation can be substantially ignorable and thus a more realistic image can be displayed because the user's eye is positioned in the normal direction of the display surface of the display portion.

The operation button 873 serves as a power button or the like. A button other than the operation button 873 may be included.

As illustrated in FIG. 27E, lenses 875 may be provided between the display portion 872 and the user's eyes. The user can see magnified images on the display portion 872 through the lenses 875, leading to higher sense of presence. In that case, as illustrated in FIG. 27E, a dial 876 for changing the position of the lenses and adjusting visibility may be included.

The display device of one embodiment of the present invention can be used for the display portion 872. Since the display device of one embodiment of the present invention has extremely high definition, even when an image is magnified using the lenses 875 as illustrated in FIG. 27E, the pixels are not perceived by the user, and thus a more realistic image can be displayed.

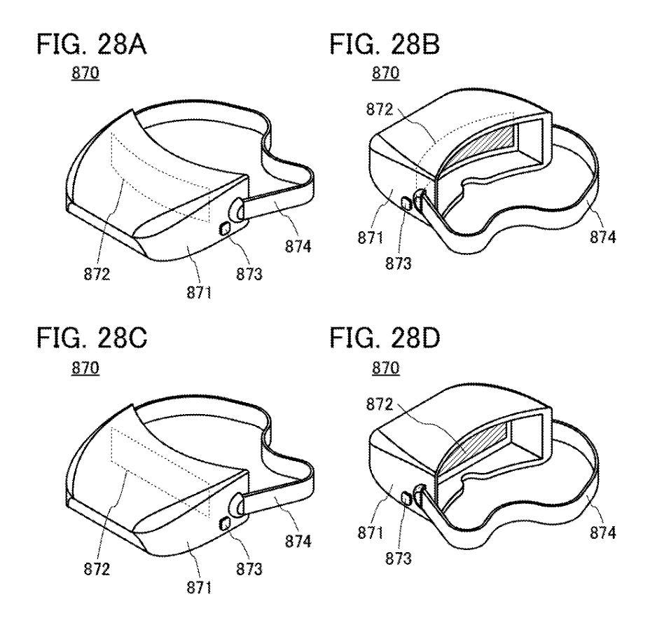

FIGS. 28A to 28C are examples in which the head-mounted display includes one display portion 872. Such a structure can reduce the number of components.

The display portion 872 can display an image for the right eye and an image for the left eye side by side on a right region and a left region, respectively. Thus, a three-dimensional moving image using binocular disparity can be displayed.

One image which can be seen by both eyes may be displayed on all over the display portion 872. A panorama moving image can thus be displayed from end to end of the field of view; thus, the sense of reality is increased.

The lenses 875 may be provided. Two images may be displayed side by side on the display portion 872. Alternatively, one image may be displayed on the display portion 872 and seen by both eyes through the lenses 875.

The display portion 872 is not necessarily curved and may have a flat display surface as shown in an example of FIGS. 28C and 28D in which the display portion 872 does not have a curved surface, for example.

At least part of this embodiment can be implemented in combination with any of the other embodiments described in this specification as appropriate.

### EXPLANATION OF REFERENCE

10: display device, 10a: display device, 11a: display panel, 11b: display panel, 20a: pixel, 20b: pixel, 20c: pixel, 20d: pixel, 21aB: display element, 21aG: display element, 21aR: display element, 21B: display element, 21G: display element, 21R: display element, 21W: display element, 22B: display element, 22G: display element, 22R: display element, 22W: display element, 31: insulating layer, 31a: insulating layer, 32: insulating layer, 33: insulating layer, 34: insulating layer, 35: insulating layer, 35a: insulating layer, 35b: insulating layer, 41a: transistor, 41b: transistor, 41c: transistor, 41d: transistor, 41e: transistor, 41f: transistor, 41g: transistor, 42a: transistor, 42b: transistor, 50: adhesive layer, 51a: substrate, 51b: substrate, 52a: substrate, 52b: substrate, 53a: adhesive layer, 53b: adhesive layer, 54a: substrate, 54b: substrate, 61a: display portion, 61b: display portion, 62a: circuit portion, 62b: circuit portion, 63a: FPC, 63b: FPC, 64a: IC, 64b: IC, 65a: wiring, 65b: wiring, 111: conductive layer, 111b: conductive layer, 111c: conductive layer, 112a: semiconductor layer, 112b: semiconductor layer, 113a: conductive layer, 113b: conductive layer, 113c: conductive layer, 113d: conductive layer, 120: light-emitting element, 120a: light-emitting element, 120b: light-emitting element, 120c: light-emitting element, 121: conductive layer, 122: EL layer, 122R: EL layer, 122G: EL layer, 122B: EL layer, 122W: EL layer, 123: conductive layer, 125: optical adjustment layer, 130: capacitor, 132: insulating layer, 133: insulating layer, 134: insulating layer, 135: insulating layer, 136: insulating layer, 137: insulating layer, 138: insulating layer, 139: insulating layer, 141: carrier-injection layer, 141B: carrier-injection layer, 141G: carrier-injection layer, 141R: carrier-injection layer, 142: carrier-transport layer, 142B: carrier-transport layer, 142G: carrier-transport layer, 142R: carrier-transport layer, 143B: light-emitting layer, 143G: light-emitting layer, 143R: light-emitting layer, 144: carrier-transport layer, 144B: carrier-transport layer, 144G: carrier-transport layer, 144R: carrier-transport layer, 145: carrier-injection layer, 145B: carrier-injection layer, 145G: carrier-injection layer, 145R: carrier-injection layer, 151a: adhesive layer, 151b: adhesive layer, 152B: coloring layer, 152G: coloring layer, 152R: coloring layer, 360: light-emitting element, 362: display portion, 400: display device, 400a: display panel, 400b: display panel, 410a: pixel, 410b: pixel, 800: portable information terminal, 801: housing, 802: housing, 803: display portion, 804: display portion, 805: hinge portion, 810: portable information terminal, 811: housing, 812: display portion, 813: operation buttons, 814: external connection port, 815: speaker, 816: microphone, 817: camera, 820: camera, 821: housing, 822: display portion, 823: operation buttons, 824: shutter button, 826: lens, 840: camera, 841: housing, 842: display portion, 843: operation buttons, 844: shutter button, 846: lens, 850: finder, 851: housing, 852: display portion, 853: button, 860: head-mounted display, 861: mounting portion, 862: lens, 863: main body, 864: display portion, 865: cable, 866: battery, 870: head-mounted display, 871: housing, 872: display portion, 873: operation buttons, 874: fixing band, 875: lens, 876: dial, 8000: display module, 8001: upper cover, 8002: lower cover, 8003: FPC, 8004: touch panel, 8005: FPC, 8006: display panel, 8009: frame, 8010: printed circuit board, 8011: battery.

This application is based on Japanese Patent Application serial No. 2016-125754 filed with Japan Patent Office on Jun. 24, 2016 and Japanese Patent Application serial No. 2016-131349 filed with Japan Patent Office on Jul. 1, 2016, the entire contents of which are hereby incorporated by reference.

1. A display device comprising:
a first display element;
a second display element;
a first transistor;
a second transistor;
a third transistor;
a fourth transistor; and
a first insulating layer,
wherein the first insulating layer is positioned above the second display element, the third transistor, and the fourth transistor,
wherein the first display element, the first transistor, and the second transistor are positioned above the first insulating layer,
wherein the first display element is electrically connected to the second transistor,
wherein the second display element is electrically connected to the fourth transistor,
wherein the first transistor is electrically connected to the second transistor,
wherein the third transistor is electrically connected to the fourth transistor,
wherein the second display element has a function of emitting a second light to a first insulating layer side, and
wherein the first display element has a function of emitting a first light to the same direction as the second light.

2. The display device according to claim 1,
wherein each of the first display element and the second display element includes a light-emitting layer, and
wherein each of the first display element and the second display element includes a coloring layer overlapping with the light-emitting layer.

3. The display device according to claim 1, further comprising a third display element,
wherein the third display element is positioned above the first insulating layer,
wherein the third display element has a function of emitting the first light to the same direction as the second light, and
wherein the first display element and the third display element include different light-emitting layers.

4. The display device according to claim 1, further comprising an adhesive layer between the first insulating layer and the second display element.

5. The display device according to claim 1,
wherein the first transistor includes a first source electrode and a first drain electrode,
wherein the second transistor is positioned above the first transistor, and
wherein one of the first source electrode and the first drain electrode serves as a gate electrode of the second transistor.

6. The display device according to claim 1, wherein the third transistor and the fourth transistor are provided on the same plane.

7. The display device according to claim 1,
wherein the third transistor includes a third source electrode and a third drain electrode,
wherein the second transistor is positioned above the third transistor, and
wherein one of the third source electrode and the third drain electrode serves as a gate electrode of the fourth transistor.

8. The display device according to claim 1,
wherein the first light and the second light are different in color.

9. The display device according to claim 1,
wherein at least one of the first transistor, the second transistor, the third transistor, and the fourth transistor includes an oxide semiconductor in its semiconductor layer where a channel is formed.

10. A display device comprising
a first display element;
a second display element;
a third display element;
a first transistor;
a second transistor;
a third transistor;
a fourth transistor; and
a first insulating layer,
wherein the first insulating layer is positioned above the second display element, the third transistor, and the fourth transistor,
wherein the first display element, the third display element, the first transistor, and the second transistor are positioned above the first insulating layer,
wherein the first display element is electrically connected to the second transistor,
wherein the second display element is electrically connected to the fourth transistor,
wherein the first transistor is electrically connected to the second transistor,
wherein the third transistor is electrically connected to the fourth transistor,
wherein the first display element and the third display element include different light-emitting layers, and
wherein the second display element is positioned between the first display element and the third display element when seen from the above.

11. The display device according to claim 10, further comprising an adhesive layer between the first insulating layer and the second display element.

12. The display device according to claim 10,
wherein the first transistor includes a first source electrode and a first drain electrode,
wherein the second transistor is positioned above the first transistor, and
wherein one of the first source electrode and the first drain electrode serves as a gate electrode of the second transistor.

13. The display device according to claim 10, wherein the third transistor and the fourth transistor are provided on the same plane.

14. The display device according to claim 10,
wherein the third transistor includes a third source electrode and a third drain electrode,
wherein the second transistor is positioned above the third transistor, and
wherein one of the third source electrode and the third drain electrode serves as a gate electrode of the fourth transistor.

15. The display device according to claim 10,
wherein at least one of the first transistor, the second transistor, the third transistor, and the fourth transistor includes an oxide semiconductor in its semiconductor layer where a channel is formed.

16. A display device comprising:
a first display element;
a second display element;
a fourth display element;
a first transistor;
a second transistor;
a third transistor;
a fourth transistor; and
a first insulating layer,
wherein the first insulating layer is positioned above the second display element, the fourth display element, the third transistor, and the fourth transistor,
wherein the first display element, the first transistor, and the second transistor are positioned above the first insulating layer,
wherein the first display element is electrically connected to the second transistor,
wherein the second display element is electrically connected to the fourth transistor,
wherein the first transistor is electrically connected to the second transistor,
wherein the third transistor is electrically connected to the fourth transistor,
wherein the second display element has a function of emitting a second light to a first insulating layer side,
wherein the fourth display element has a function of emitting a fourth light to the first insulating layer side,
wherein the first display element has a function of emitting a first light to the same direction as the second light, and
wherein the second display element and the fourth display element include different light-emitting layers.

17. The display device according to claim 16,
wherein the first display element is positioned between the second display element and the fourth display element when seen from the above.

18. The display device according to claim 16, further comprising an adhesive layer between the first insulating layer and the second display element.

19. The display device according to claim 16,
wherein the first transistor includes a first source electrode and a first drain electrode,
wherein the second transistor is positioned above the first transistor, and
wherein one of the first source electrode and the first drain electrode serves as a gate electrode of the second transistor.

20. The display device according to claim 16, wherein the third transistor and the fourth transistor are provided on the same plane.

21. The display device according to claim 16,
wherein the third transistor includes a third source electrode and a third drain electrode,
wherein the second transistor is positioned above the third transistor, and
wherein one of the third source electrode and the third drain electrode serves as a gate electrode of the fourth transistor.

22. The display device according to claim 16,
wherein the first light and the second light are different in color.

23. The display device according to claim 16,
wherein at least one of the first transistor, the second transistor, the third transistor, and the fourth transistor includes an oxide semiconductor in its semiconductor layer where a channel is formed.
